(19) United States
(12) Patent Application Publication
(10) Pub. No.: US 2012/0103412 A1
(43) Pub. Date: May 3, 2012

(54) METHOD FOR FABRICATING A LASER-INDUCED SURFACE NANOARRAY STRUCTURE, AND DEVICE STRUCTURE FABRICATED USING SAID METHOD

(76) Inventors: Takahiko Kato, Hitachinaka (JP); Seiichi Watanabe, Sapporo (JP); Shigeo Yatsu, Sapporo (JP); Satoshi Kayashima, Sapporo (JP); Norihiko Nishiguchi, Sapporo (JP); Hiroaki Misawa, Sappporo (JP); Kiyotaka Asakura, Sapporo (JP)

(21) Appl. No.: 13/322,156

(22) PCT Filed: May 25, 2010
(86) PCT No.: PCT/JP2010/003491

§ 371 Date: Jan. 17, 2012

(30) Foreign Application Priority Data
May 25, 2009 (JP) 2009-125233

(51) Int. Cl. H01L 31/0236; B32B 3/14; C30B 11/12; B82Y 40/00; B82Y 30/00

(52) U.S. Cl. 136/256; 428/206; 117/12; 977/774

(57) ABSTRACT

Provided is a method for manufacturing a two-dimensional pattern by simultaneously forming a plurality of quantum dots on a surface of a solid material and making the quantum dots a periodic structure by a laser irradiation, and a device structure and a device fabricated by the method.
The method for fabricating a quantum dot-formed surface including the laser irradiation which irradiate at least one batch of laser onto a surface of a solid material to simultaneously form a plurality of quantum dots on the surface, arranging the plurality of quantum dots into periodic arrays.

### FIELD OF THE INVENTION

The present invention relates to a method for arraying dot-shaped objects induced by laser irradiation in a nano-order on a surface to process them, and to a functional device fabricated by using the method, such as an electronic and electromagnetic device, quantum dot device, optoelectronic device, solar cell material, and patterned catalyst material, and to a functional material for patterned media.

### BACKGROUND ART

A quantum dot means a structure in which electrons and holes are confined within a small three-dimensional area which has a size of several nanometers to several tens nanometers. Herein, a dot-shaped object on a surface, corresponding to such a structure, is referred to as a quantum dot.

In a semiconductor or a metal, a degree of freedom of motion of an electron can be determined by the structure of a quantum dot. In contrast to a bulk in which an electron can move three-dimensionally and freely, a quantum well in which an electron can move only two-dimensionally, and a quantum wire in which an electron can move only one-dimensionally, the quantum dot can create a system in which an electron is confined within a small area (zero-dimensional electron system). The movement of the electron confined within a quantum dot is quantized and discrete energy levels are formed.

Accordingly, the electron confined within a quantum dot remains in a certain energy level, which is greatly different from the behaviors of the electron in a bulk that takes continuous band structures so as to freely move around. Also, a single electron spin can be controlled in a quantum dot, and accordingly a light emission property and an electrical property with efficiencies higher than those of a semiconductor can be exhibited.

Examples of a method for fabricating a quantum dot include a self-organized growth method and a droplet epitaxy method, etc., and a Stranski-Krastanow crystal growth method which is one of the self-organized growth methods is the current mainstream. That is, in the self-organized growth method (Stranski-Krastanow crystal growth method), the quantum dot is formed by using a strain energy occurring due to a lattice mismatching generated when a crystal having a lattice constant different from that of a substrate is formed on the substrate. In addition, in the droplet epitaxy method, molecules having a low melting point are irradiated onto a substrate in a beam-like manner in a vacuum environment. Many fine droplets having a uniform size are formed at the time, and the droplets form quantum dots.

As a material for a quantum dot, many of Group II to IV compound semiconductors such as InAs and GaAs are used; and a research for fabricating a quantum dot using a material such as Si, an organic material or the like is being performed for the purpose of being used in various industrial fields in the future.

It is expected that quantum dots will be applied to laser, optical amplifiers, single-photon emission devices, etc. in an electronics field, to quantum cryptography communication and quantum computers, etc. in an information and communication field, to solar cells, etc. in an environment and energy field, and to bio sensors and fluorescent markers, etc. in a life science field, and some of them have been put in practical use.

On the other hand, there has never been the case in the world where a plurality of quantum dots or array structures each including the quantum dots are fabricated with laser irradiation. For processing techniques using laser irradiation, a method using a top-down method in which an irradiated area is chipped off by narrowing down a laser beam with a lens, etc. is known as a usual method.

A case example where it has been succeeded for the first time to achieve by this processing technique, a structure that striped undulations called a ripple pattern have been periodically arrayed on a surface of a material selected from Ge, Si, Al, and brass is described in Non-Patent Document 1. However, quantum dots and array structures including them have not been fabricated yet.

Additionally, in a patterning by a surface processing using a top-down method such as photo-etching, a minimum size is equal to the wavelength of light, and hence the threshold limit of a minimum processing size becomes a micrometer order.

For example, a technique in which a laser is used for the fabrication of semiconductor apparatuses is disclosed in Patent Document 1. In the technique, however, lines are only formed and a dot-shaped array object is not fabricated.

On the other hand, in the case of a bottom-up method using surface self-organization such as a CVD, the interval can be reduced to a several tens nanometer size. However, it is difficult to make a pattern having an arbitrary shape.

Additionally, a fine processing technique is disclosed in Patent Document 2, in which fine structures including protrusions each having a size smaller than the wavelength of an irradiated laser are formed on the surface of a solid material by irradiating ultra-short pulse laser (femtosecond laser) with low fluence that has been subjected to polarization control. However, the protrusions are randomly formed on the surface, and hence a structure aligned with each other which is required as the quantum dots is not obtained.

Additionally, it is not described in Patent Document 2 that the quantum dots that have been aligned with each other cannot be formed and periodic arrays of structures each having a quantum dot shape cannot be formed into a two-dimensional pattern when the femtosecond laser is used.

### PRIOR ART DOCUMENTS

### Patent Documents

Patent Document 1: Japanese Patent Application Laid-Open No. 2004-119919
Patent Document 2: Japanese Patent Application Laid-Open No. 2003-211400

### Non-Patent Document

Non-Patent Document 1: J. F. Young, J. S. Preston, H. M. van Driel, and J. E. Sipe: “Laser-induced periodic structure. II. Experiments on Ge, Si, Al, and brass”, Physical Review B, vol. 27, No. 2 (1983), p. 1155
Non-Patent Document 2: B. Ziberi et al., Phys. Rev. B, vol. 72 (2005) p. 235310
Non-Patent Document 3: C. H. Crouch et al., Appl. Phys. Lett., vol. 84 (2004) p. 1850

### DISCLOSURE OF THE INVENTION

### Problem to be Solved by the Invention

An object of the present invention is to provide a shorter periodic structure than a wavelength of a laser the periodic structure being formed with a plurality of quantum dots on a surface of a solid.

### Means for Solving the Problem

A method for fabricating a quantum dot-formed surface according to the present invention includes a step of forming simultaneously a plurality of quantum dots arranged into periodic arrays on a surface of a solid material by irradiating at least one batch of laser onto the surface.

### Effects of the Invention

According to the present invention, both operations of the patterning using a coherency of a laser beam (top-down method) and the self-organization of the surface atoms under the irradiation of the laser beam (bottom-up method) can be simultaneously utilized, thereby allowing the patterning of surface quantum dots to be made.

Further, according to the present invention, the shorter periodic structure than the wavelength of laser formed with the plurality of quantum dots on the surface of a solid can be obtained.

### BRIEF DESCRIPTION OF THE DRAWINGS

FIG. 1 is a set of FE-SEM images illustrating a quantum dot pattern array structure according to an example formed on a (100) surface of single crystal Si with a laser irradiation.

FIG. 2 is a perspective view illustrating a result of atomic force microscope (AFM) measurement of the quantum dot pattern array structure in FIG. 1.

FIG. 3A is a set of TEM images illustrating a section in Y direction of the quantum dot pattern array structure in FIG. 1.

FIG. 3B is a set of TEM images illustrating a section in X direction of the quantum dot pattern array structure in FIG. 1.

FIG. 3C is a graph illustrating an EDX analysis result of a quantum dot surface area 7 (microcrystal assembly area) in FIG. 3B.

FIG. 4 illustrates a result of AFM measurement of a ripple pattern (comparative example) formed on a surface of Si irradiated with Xe⁺ ion.

FIG. 5 is a set of SEM images illustrating a structure (comparative example) on the surface of Si irradiated with a femtosecond laser and nanosecond laser.

FIG. 6A is an SEM image illustrating a quantum dot pattern array structure on a (100) surface of Si, the structure being formed with a laser irradiation according to another example.

FIG. 6B is an SEM image illustrating an enlarged part of FIG. 6A.

FIG. 7 is a perspective view illustrating a result of AFM measurement of the quantum dot pattern array structure in FIGS. 6A and 6B.

FIG. 8A is an SEM image illustrating the quantum dot pattern array structure in FIGS. 6A and 6B.

FIG. 8B is an autocorrelation image calculated by Fourier transform from FIG. 8A.

FIG. 8C is a graph illustrating a line intensity profile taken along Line A-B illustrated in FIG. 8B.

FIG. 8D is a graph illustrating a line intensity profile taken along Line C-D illustrated in FIG. 8B.

FIG. 9A is an SEM image illustrating an elementary process (at the beginning) of forming quantum dots on a (100) surface of Si by laser irradiation within an ultrahigh voltage electron microscope.

FIG. 9B is an SEM image illustrating an elementary process (after 3 pulses) of forming quantum dots on the (100) surface of Si by laser irradiation within the ultrahigh voltage electron microscope.

FIG. 9C is an SEM image illustrating an elementary process (after 7 pulses) of forming quantum dots on the (100) surface of Si by laser irradiation within the ultrahigh voltage electron microscope.

FIG. 9D is an SEM image illustrating an elementary process (after 10 pulses) of forming quantum dots on the (100) surface of Si by laser irradiation within the ultrahigh voltage electron microscope.

FIG. 9E is an SEM image illustrating an elementary process (after 20 pulses) of forming quantum dots on the (100) surface of Si by laser irradiation within the ultrahigh voltage electron microscope.

FIG. 9F is an SEM image illustrating an elementary process (after 27 pulses) of forming quantum dots on the (100) surface of Si by laser irradiation within the ultrahigh voltage electron microscope.

FIG. 10 is a result of AFM measurement of a line profile of a surface quantum dot sequence.

FIG. 11A is an SEM image illustrating an experimental result of a parameter (wavelength dependence) by which a controllability of a quantum dot pattern is affected.

FIG. 11B is an SEM image illustrating a result of the experiment of a parameter (inclination of a laser beam (S-wave: 30°)) by which the controllability of a quantum dot pattern is affected.

FIG. 11C is an SEM image illustrating a result of the experiment of a parameter (inclination of the laser beam (S-wave: 45°)) by which the controllability of a quantum dot pattern is affected.

FIG. 11D is an SEM image illustrating a result of the experiment of a parameter (polarization) by which the controllability of a quantum dot pattern is affected.

FIG. 11E is an SEM image illustrating a result of the experiment of a parameter (plane orientation dependence of a target material ((111) surface of Si) by which the controllability of a quantum dot pattern is affected.

FIG. 12A is a schematic perspective view illustrating a test apparatus for a laser irradiation in the atmosphere.

FIG. 12B is a photograph illustrating a state of a laser irradiation test by using the test apparatus for the laser irradiation in the atmosphere.

FIG. 13A is a schematic view illustrating a laser irradiation system according to an example.

FIG. 13B is a schematic view illustrating a laser irradiation system according to a comparative example.

FIG. 14 is a schematic view illustrating a laser irradiation-inclining table used for inclining a laser beam.

FIG. 15A is a schematic view illustrating a state of an inclined laser irradiation (case of an S-wave).

FIG. 15B is a schematic view illustrating a state of an inclined laser irradiation (case of a P-wave).

FIG. 16A is an SEM image illustrating a change in a pattern of quantum dot sequences by a horizontal polarization according to an example.

FIG. 16B is an SEM image illustrating an enlarged part of FIG. 16A.

FIG. 16C is an SEM image illustrating a change in the pattern of quantum dot sequences by 90° rotation of the polarization according to an example.

FIG. 16D is an SEM image illustrating an enlarged part of FIG. 16C.

FIG. 17A is an SEM image illustrating a quantum dot two-dimensional pattern according to an example formed by using a polarization (1) in FIG. 15A.

FIG. 17B is an SEM image illustrating a quantum dot two-dimensional pattern according to an example formed by using a polarization (2) in FIG. 15A.

FIG. 17C is an SEM image illustrating a quantum dot two-dimensional pattern according to an example formed by using a polarization (3) in FIG. 15B.

FIG. 17D is an SEM image illustrating a quantum dot two-dimensional pattern according to an example formed by using a polarization (4) in FIG. 15B.

FIG. 18A is an SEM image illustrating a quantum dot two-dimensional pattern according to another example formed by using the polarization (1) in FIG. 15A.

FIG. 18B is an SEM image illustrating a quantum dot two-dimensional pattern according to another example formed by using the polarization (2) in FIG. 15A.

FIG. 18C is an SEM image illustrating a quantum dot two-dimensional pattern according to another example formed by using the polarization (3) in FIG. 15B.

FIG. 18D is an SEM image illustrating a quantum dot two-dimensional pattern according to another example formed by using the polarization (4) in FIG. 15B.

FIG. 19A is an SEM image illustrating a result of evaluation of an influence by an irradiated plane orientation of single crystal Si on a formation of a quantum dot two-dimensional pattern.

FIG. 19B is an SEM image illustrating an enlarged part of FIG. 19A.

FIG. 20A is an SEM image illustrating a quantum dot two-dimensional pattern-formed surface according to an example, the pattern having a square shape.

FIG. 20B is an SEM image illustrating an enlarged part of FIG. 20A.

FIG. 21A is an SEM image illustrating a quantum dot two-dimensional pattern-formed surface according to an example, the pattern having a diamond shape.

FIG. 21B is an SEM image illustrating an enlarged part of FIG. 21A.

FIG. 22 is an SEM image illustrating a quantum dot two-dimensional pattern-formed surface according to an example, in which large and small dots exist in a mixed manner.

FIG. 23A is an SEM image illustrating a quantum dot two-dimensional pattern-formed surface according to an example, the pattern having a honeycomb structure.

FIG. 23B is an SEM image illustrating an enlarged part of FIG. 23A.

FIG. 24 is an SEM image illustrating a quantum dot two-dimensional pattern according to an example formed on a surface of a Zn-doped GaAs material.

FIG. 25 is a graph illustrating a result of measurement of a photoluminescence of a quantum dot pattern according to an example.

FIG. 26A is an SEM image illustrating an area for measurement of photoelectron emission in a quantum dot pattern according to an example.

FIG. 26B is an image illustrating a result of the measurement (without a filter) of photoelectron emission in the quantum dot pattern according to the example.

FIG. 26C is an image illustrating a result of the measurement (with a filter) of photoelectron emission in the quantum dot pattern according to the example.

FIG. 27A is a TEM image illustrating quantum dots on a surface of Si irradiated with a nanosecond pulse laser (500 pulses) within the ultrahigh voltage electron microscope.

FIG. 27B is a TEM image illustrating quantum dots on a surface of Si irradiated with a nanosecond pulse laser (550 pulses) within the ultrahigh voltage electron microscope.

FIG. 27C is a TEM image illustrating quantum dots on a surface of Si irradiated with a nanosecond pulse laser (600 pulses) within the ultrahigh voltage electron microscope.

FIG. 27D is an image illustrating an electron diffraction pattern (RHEED image) taken from a cone-shaped quantum dot.

FIG. 28A is a set of TEM images illustrating circular quantum dots formed on a surface of Si irradiated with a nanosecond pulse laser within the ultrahigh voltage electron microscope.

FIG. 28B is a TEM image illustrating an enlarged part of FIG. 28A.

FIG. 29A is an SEM image illustrating a structure on (100) surface of single crystal Si according to a comparative example, the surface being irradiated with half-wavelength laser.

FIG. 29B is an SEM image illustrating a structure on (100) surface of single crystal Si according to another comparative example, the surface being irradiated with half-wavelength laser.

FIG. 30 is an SEM image illustrating a structure on a surface of Si-doped GaAs according to a comparative example, the surface being irradiated with laser.

FIG. 31A is an SEM image illustrating a structure on (100) surface of single crystal Si according to a comparative example, the surface being irradiated with a femtosecond pulse laser.

FIG. 31B is an SEM image illustrating a structure on a surface of 6H—SiC according to a comparative example, the surface being irradiated with a femtosecond pulse laser.

FIG. 32A is an SEM image illustrating a structure on (100) surface of single crystal Si according to a comparative example, the surface being irradiated with a laser under a condition in which a laser intensity has been increased.

FIG. 32B is an enlarged SEM image illustrating a cone-shaped organization formed in a periphery of an irradiated area illustrated in FIG. 32A.

FIG. 33A is a sectional TEM image illustrating a quantum dot pattern according to another example.

FIG. 33B is an enlarged sectional TEM image illustrating the quantum dot pattern in FIG. 33A.

### MODES FOR CARRYING OUT THE INVENTION

General problems to be solved with respect to a quantum dot will be first described.

The monochromaticity or intensity of emitted light can be enhanced by making the size of each quantum dot to be uniform. For example, it becomes possible to enhance the performance of a quantum dot laser, and accordingly it is an important challenge to make quantum dots to be uniform.

As an indicator for the uniformity of the size of quantum dots, a width (=PL half-width) of an emission spectrum is used, which indicates that the size is more uniform as the PL half-width is smaller. It is a very important challenge to increase an area density of the quantum dots and to make the structure of the quantum dot to be fine in terms of increasing the number of carriers and enhancing the performance of the laser or an optical amplifier.

In addition, at present, an array of the quantum dots can be controlled by operating a scanning probe microscope (SPM). However, the quantum dots do not emit light in the case, and hence there is a demand for high-quality control of the arrays in which light can be emitted.

When the high-quality control of the arrays becomes possible, for example, it is expected that a quantum dot solar cell in which regular arrays of quantum dots are needed may be put into a practical use, and that a device structure for a quantum dot computers may be fabricated.

In order to apply the quantum dots in various industrial fields, it is needed to develop new materials such as a GaN-based compound semiconductor, Si, C and an organic material other than InAs and GaAs that have currently been employed. Additionally, because a material used in a quantum dot contains Cd, Hg, As, etc., it is demanded to develop a quantum dot whose material does not contain such elements.

As stated above, the Stranski-Krastanow crystal growth method (SK mode method) which is one of the self-organized growth methods is the mainstream in methods for fabricating quantum dots. However, because the control of the size and arrays of the dots is insufficient, it becomes a challenge to develop an easy fabrication method in which the size and arrays can be controlled. It is also needed to develop a completely new fabrication method by which it is intended to fabricate quantum dots at low coat and on a large scale in the future. To achieve the quantum cryptography communication and the quantum computer, it is needed to keep a long coherence time (a period of time during which an overlapping state of quantum states is held and the quantum dots are in a state of being calculated) and to perform stabilized information transfer.

It is expected that the control of the structure of the quantum dot at a nano-size level will solve the challenges with respect to such control of physical properties.

In view of the aforementioned problems, a first object of the present invention is to provide a method for forming periodic structures by which periodic dot shapes are simultaneously formed with laser irradiation, and a method for fabricating a periodic structure-formed surface on which the periodic dot shapes (periodic structures) are arranged into a two-dimensional pattern (a method for forming a two-dimensional pattern array), these methods having never been achieved in the world.

Further, a second object of the present invention is to provide various quantum devices, functional devices, electronic and information devices, and energy devices, etc., each of which has the quantum dot structure-formed surface provided with the aforementioned dot-shaped periodic structures by laser.

In the present invention, conditions under which both functions of a patterning using a coherency of a beam laser (top-down method) and a self-organization of surface atoms under the irradiation of the laser beam (bottom-up method) can be simultaneously exhibited have been found, taking into consideration that the aforementioned method for forming periodic structures and method for forming a two-dimensional pattern array cannot be provided only with a top-down effect by the laser.

That is, it has been found that a solid surface (surface of a solid material) provided with the quantum dot two-dimensional periodic pattern array can be fabricated when new laser irradiation conditions under which a top-down effect and a bottom-up effect are simultaneously utilized under laser beam irradiation are set as follows: the laser is nanosecond pulse laser; and the laser is irradiated under the conditions of 4.0×10² to 4.0×10³ J/m²/pulse, 2 to 20 Hz, and the pulse number of 500 to 5000 pulses (both inclusive). Herein, as the solid material, an inorganic material such as a semiconductor, metal, alloy, ceramics or the like is used.

Further, under this laser irradiation conditions, the diameter of a quantum dot is 1 to 100 nanometers, and the height thereof can be freely controlled within a range from a nanometer order to a micrometer order by changing an irradiation amount.

Furthermore, in the present invention, a technique in which patterns are arrayed such that a dot interval width is shorter than the wavelength of the laser is provided by controlling quantum nature (wave nature and particle nature) of the laser, i.e., the particle nature of the light beam by which surface sputtering is generated and the nature as a wave. Accordingly, the laser is irradiated directly onto a sample without collecting the laser with a lens typically used in a laser processing so as to have a high intensity (without the use of the lens), and it is made that the vibrations of all optical apparatuses installed from the position where the laser has been installed to the position where the sample has been fixed are synchronized with each other by fabricating a laser oscillator-integrated optical and sample-fixing platen for including all components from the laser to the sample in the same system.

Thereby, it becomes possible to fabricate a laser-induced surface nanoarray of a plurality of quantum dots by irradiating linearly-polarized laser whose intensity and irradiation amount are controlled.

Further, it has been found that a surface organization can be controlled by the following four means as means of controlling a quantum dot array structure (hereinafter, referred to as an organization) including the quantum dots on the solid surface: (1) an organization control by the wavelength of the laser; (2) an organization control by a polarization direction; (3) an organization control by an irradiation angle; and (4) an organization control by a target material.

The laser used in the experiments with respect to (1) were Inlite II-532 and Inlite II-266.

In the experiments with respect to (2), a half-wave plate was used to change the polarization.

In the experiments with respect to (4), substrates including not only (100) surface of Si but (111) surface of Si, Si-doped or Zn-doped GaAs, and a substrate formed of 6H—SiC or SiC fabric were perpendicularly irradiated with the laser.

In our typical research, the diameter of the laser beam was 6 mm, and when a sample was observed after being irradiated, it was cut into a square shape having a size of approximately 10 mm×10 mm with a diamond pen so that the whole area irradiated with the laser beam could be observed. The sample was fixed so as to be perpendicular to the laser beam.

A mark was first made on a fixed stainless plate by irradiating laser thereto such that a sample was fixed there with a carbon tape. When an irradiation angle was to be changed, the change was made based on the angle from the perpendicular direction.

When the laser beam was collected, a lens was appropriately placed in the laser path.

The present technique is a so-called bottom-up and top-down combined device fabrication method in which the bottom-up technique self-organizing chipped off surface atoms into a particulate manner by reattaching the atoms onto the surface, and a top-down technique in which inducing a two-dimensional surface dot pattern by controlling the nature of the laser as a wave are combined together. It is a new and basic means substantially provided in which can fabricate various devices, materials and structures which will be described in the following Effects of the Invention.

Hereinafter, the research leading to the present invention and embodiments of the present invention will be described.

The results of our research will be first summarized in an itemized form.

1) When a nanosecond pulse laser is irradiated in the atmosphere under a conditions of 4.0×10² to 4.0×10³ J/m²/pulse, 2 to 20 Hz, and the pulse number of 500 to 5000 pulses, a two-dimensional periodic pattern array formed with a plurality of quantum dots is generated.

2) The typical size of the quantum dot periodically arrayed on a surface (periodically arrayed quantum dot) is 10 to 100 μm in height and 5 nm to 50 nm in diameter; however, the height can be changed up to 1 μm or more and the diameter can be changed within a range of 1 nm to 100 nm. In addition, the interval between the arrays is approximately ¼ to ⅕ times the wavelength (100 to 130 nm).

3) Although ripple patterns (striped undulations) are generated so as to be arrayed at a wavelength interval and to be perpendicular to a polarization plane, it is for the first time that striped lines having a ripple pattern can be formed by an array of aligned quantum dots.

4) A quantum dot crystal undergoes crystal growth (epitaxial) in the same orientation as that of the surface (foundation) irradiated with the laser. This shows the evidence that a bottom-up effect involving melting occurs, which means that atomic clusters (debris) desorbed from the surface (an excitation effect by an ablation) by the pulse laser irradiation spreads on the surface, undergoes a dot growth and is arrayed at constant intervals (organized) by the subsequent irradiation and a thermal effect due to the irradiation.

5) The formation of the quantum dot crystals is not dependent on the surface orientation. That is, for example, the same quantum dot patterns are generated on the (100) surface and (111) surface of Si under the same laser irradiation conditions.

6) Results of the research in which a single crystal Si semiconductor was treated has been described above; however, the same phenomena were observed in the research in which another substances such as GaAs were treated.

7) The surface quantum dots are arrayed perpendicularly to the laser polarization plane.

8) It was possible to change the array direction of the quantum dots by controlling the laser polarization direction or by inclining the polarization direction.

9) It was possible to control the interval between the quantum dots by inclining the polarization direction of the irradiated laser.

10) It is possible to array the quantum dots into an arbitrary two-dimensional pattern by sequentially or simultaneously performing superimposed irradiation.

11) When photoluminescence of the surface provided with quantum dot shapes was measured, a characteristic photoluminescence peak appeared near 600 nm. Thereby, it was proved that the surface had a function as a quantum device.

12) It has been proved by using a photoelectron emission microscope (PEEM) that a ripple pattern area has a working function of 5.6 eV or more and another area has that of approximately 5.0 eV, and accordingly the surface has different surface photoelectron emission properties, i.e., the surface has a characteristic property as a surface functional device important for a catalytic action etc.

13) As an irradiation intensity or irradiation amount was increased, the quantum dot continued to grow into a cone shape, thereby allowing the height thereof to be approximately 100 nm to 1 μm.

14) It became possible to form a pattern in which quantum dots were circularly aligned with each other by providing a temperature gradient on the surface.

15) Because it becomes possible to provide a characteristic photoluminescence peak and a surface photoelectron property by the surface quantum dots and an array thereof, it has been made clear that this method is effective as a technique for fabricating an optoelectronic device, quantum dot laser, semiconductor integrated device and patterned catalyst device.

A method for fabricating a quantum dot-formed surface according to the present invention comprises irradiating laser onto a surface of a solid material to simultaneously form a plurality of quantum dot structures each having a quantum dot shape with one batch laser irradiation, and to periodically array the quantum dot structures on the surface.

Herein, the batch means what is represented by a batch process that is typically used and one of engineering terms, and generally means one bundle, one step, an amount at one time, and a bunch of quantity, bundle or cluster.

Accordingly, the one batch irradiation means a laser irradiation at one time. Namely, it means a laser irradiation including multiple pulses.

In the method for fabricating the quantum dot-formed surface according to the present invention, the periodic arrays of the quantum dot structures are arranged into a two-dimensional pattern by simultaneously forming a plurality of quantum dot structures with one batch irradiation on the surface, and by combining multiple processes in each of which the quantum dot structures are periodically arrayed with the polarization for each batch being changed to sequentially perform superimposed irradiation on the same place.

In the method for fabricating the quantum dot-formed surface according to the present invention, a simultaneous superimposed irradiation combining multiple polarizations changed in a batch and irradiating onto the same place is performed.

The method for fabricating the quantum dot-formed surface according to the present invention forms a two-dimensional pattern in which the quantum dot structures are aligned with each other in a linear or curved line.

A method for fabricating the quantum dot two-dimensional periodic pattern array-formed surface according to the present invention is one using the aforementioned method for fabricating the quantum dot-formed surface, in which the laser irradiation is performed with the use of a polarized pulse laser irradiation in vacuum or in the atmosphere without the use of a collecting lens so that the surface dots are arrayed simultaneously into periodic structures formed by the wave nature of laser, and into short-periodic structures formed by the bottom-up method using the self-organization function of the surface atoms and which have an interval shorter than the wavelength of the laser.

In the method for fabricating the quantum dot two-dimensional periodic pattern array-formed surface according to the present invention, the laser beam is nanosecond pulse laser, and is irradiated under the conditions of 4.0×10² to 4.0×10³ J/m²/pulse and 2 to 20 Hz; and the pulse number of 500 to 5000 pulses.

In the method for fabricating the quantum dot two-dimensional periodic pattern array-formed surface according to the present invention, the diameter of the quantum dot is 1 to 100 nanometers, and the height thereof can be freely controlled up to a micrometer by changing an irradiation amount.

The quantum dot two-dimensional periodic pattern array-formed surface structure according to the present invention is one fabricated by the aforementioned method for fabricating the quantum dot two-dimensional periodic pattern array-formed surface by irradiating linearly-polarized laser, the structure having linear dot arrays having an interval within an error range of 10% or less with respect to the wavelength of the linearly-polarized laser, and regular arrays having an interval between the dots in the line is ¼ to ⅕ times the wavelength.

Herein, the expression of “having an interval within an error range of 10% or less with respect to the wavelength” means that d is within a range of 0.9λ to 1.1λ when the wavelength is indicated by λ and the interval by d.

In the method for fabricating the quantum dot two-dimensional periodic pattern array-formed surface according to the present invention, a crystal having striped undulations which is constructed of the quantum dots aligned with each other undergoes an epitaxial growth from the surface of the solid material that is a foundation.

The quantum dot two-dimensional periodic pattern array-formed surface structure according to the present invention is one fabricated by the aforementioned method for fabricating the quantum dot two-dimensional periodic pattern array-formed surface, in which a crystal having striped undulations which is constructed of the quantum dots aligned with each other undergoes an epitaxial growth from the surface of the solid material that is a foundation.

In the method for fabricating the quantum dot-formed surface according to the present invention, the quantum dots are arranged into a two-dimensional pattern by using the sequential irradiation or the superimposed irradiation of the laser beams.

In the method for fabricating the quantum dot two-dimensional periodic pattern array-formed surface according to the present invention, the quantum dots are arranged into a two-dimensional pattern by using the sequential irradiation or the superimposed irradiation of the laser beams.

In the method for fabricating the quantum dot-formed surface according to the present invention, the irradiation of the laser beams is performed while a process of fabricating a quantum dot pattern is being observed in situ within a laser-equipped electron microscope (electron microscope in which a laser generator has been built-in).

In the method for fabricating the quantum dot two-dimensional periodic pattern array-formed surface according to the present invention, the irradiation of the laser beams is performed while a process of fabricating a quantum dot pattern is being observed in situ within the laser-equipped electron microscope.

In the method for fabricating the quantum dot-formed surface according to the present invention, the irradiation of the laser beams is performed in the atmosphere by using the laser oscillator-integrated optical and sample-fixing platen.

In the method for fabricating the quantum dot two-dimensional periodic pattern array-formed surface according to the present invention, the irradiation of the laser beams is performed in the atmosphere by using the laser oscillator-integrated optical and sample-fixing platen.

The electronic and electromagnetic device according to the present invention is fabricated by using the aforementioned method for fabricating a quantum dot-formed surface or the aforementioned method for fabricating the quantum dot two-dimensional periodic pattern array-formed surface.

The quantum dot device according to the present invention is fabricated by using the aforementioned method for fabricating the quantum dot-formed surface or the aforementioned method for fabricating the quantum dot two-dimensional periodic pattern array-formed surface.

The optoelectronic device according to the present invention is fabricated by using the aforementioned method for fabricating the quantum dot-formed surface or the aforementioned method for fabricating the quantum dot two-dimensional periodic pattern array-formed surface.

The solar cell according to the present invention is fabricated by using the aforementioned method for fabricating the quantum dot-formed surface or the aforementioned method for fabricating the quantum dot two-dimensional periodic pattern array-formed surface.

The patterned catalyst material according to the present invention is fabricated by using the aforementioned method for fabricating the quantum dot-formed surface or the aforementioned method for fabricating the quantum dot two-dimensional periodic pattern array-formed surface.

The functional surface device according to the present invention is fabricated by using the aforementioned method for fabricating the quantum dot-formed surface or the aforementioned method for fabricating the quantum dot two-dimensional periodic pattern array-formed surface.

The functional material for the patterned media according to the present invention is fabricated by using the aforementioned method for fabricating the quantum dot-formed surface or the aforementioned method for fabricating the quantum dot two-dimensional periodic pattern array-formed surface.

The quantum dot laser according to the present invention is fabricated by using the aforementioned method for fabricating the quantum dot-formed surface or the aforementioned method for fabricating the quantum dot two-dimensional periodic pattern array-formed surface.

The optical amplifier according to the present invention is fabricated by using the aforementioned method for fabricating the quantum dot-formed surface or the aforementioned method for fabricating the quantum dot two-dimensional periodic pattern array-formed surface.

The device for quantum cryptography communication and quantum computers according to the present invention is fabricated by using the aforementioned method for fabricating the quantum dot-formed surface or the aforementioned method for fabricating the quantum dot two-dimensional periodic pattern array-formed surface.

The optoelectronic device according to the present invention has a photoluminescence peak near 600 nm.

The quantum dot device according to the present invention has a photoluminescence peak near 600 nm.

The patterned catalyst material according to the present invention has a surface photoelectron property in which a work function is about 5.6 eV or more which is 0.6 to 1.2 eV higher than that of another area (4.4 to 5.0 eV) as an additional energy.

The functional device according to the present invention has a surface photoelectron property in which a work function is about 5.6 eV or more which is 0.6 to 1.2 eV or more higher as an additional energy than that of another area (4.4 to 5.0 eV).

The quantum dot-formed surface structure according to the present invention is fabricated by simultaneously forming the plurality of quantum dots with laser irradiation such that the plurality of quantum dot structures are patterned on the surface.

The quantum device according to the present invention is fabricated by simultaneously forming the plurality of quantum dots with laser irradiation such that the plurality of quantum dot structures are patterned on the surface.

The quantum dot-formed surface structure according to the present invention was made by simultaneously fabricating the plurality of quantum dots with the laser irradiation, and was constructed of a uniform material of the plurality of quantum dots undergoing the epitaxial growth from the crystals of the foundation and the plurality of quantum dot structures patterned on the surface.

The quantum dot device according to the present invention was made by simultaneously fabricating the plurality of quantum dots with the laser irradiation, and was constructed of a uniform material of the plurality of quantum dots undergoing the epitaxial growth from the crystals of the foundation and the plurality of quantum dot structures patterned on the surface.

The method for fabricating the quantum dot-formed surface according to the present invention includes a step of irradiating at least one batch of laser onto the surface of the solid material to simultaneously form the plurality of quantum dots arranged into periodic arrays on the surface.

In the step of the method for fabricating the quantum dot-formed surface according to the present invention, the arrays are arranged into the two-dimensional pattern by sequentially performing the laser irradiation at multiple times, and in each of the laser irradiation, the superimposed irradiation is performed onto the same place on the surface by using the plurality of polarized light each having an incident angle with respect to the surface, the angle being different from the others.

In the method for fabricating the quantum dot-formed surface according to the present invention, the arrays are arranged into the two-dimensional pattern by using the laser irradiation in which the superimposed irradiation is performed on the same place of the surface by using the plurality of polarized light each having an incident angle with respect to the surface, the angle being different from the others.

The method for fabricating the quantum dot-formed surface according to the present invention forms the two-dimensional pattern in which the sequences are aligned with each other in a linear or curved line.

In the method for fabricating the quantum dot-formed surface according to the present invention, the laser irradiation is performed such that the surface dots are arrayed into the periodic structures formed by the wave nature of the laser used in the laser irradiation with the use of polarized pulse laser irradiation under reduced pressure or the atmosphere, without the use of the collecting lens, and into the short-periodic structures formed by the bottom-up method using the self-organization function of the atoms of the surface, the short-periodic structures having an interval shorter than the wavelength of the laser.

In the method for fabricating the quantum dot-formed surface according to the present invention, the laser is a nanosecond pulse laser, and the laser is irradiated under the conditions of 4.0×10² to 4.0×10³ J/m²/pulse, 2 to 20 Hz, and the pulse number of 500 to 5000 pulses.

In the method for fabricating the quantum dot-formed surface according to the present invention, the diameter of the quantum dot is 1 to 100 nm, and the height of the quantum dot can be freely controlled up to 1 μm by changing the irradiation amount.

In the method for fabricating the quantum dot-formed surface according to the present invention, the crystal having striped undulations which is formed by the quantum dots being aligned with each other undergoes the epitaxial growth from the surface.

In the method for fabricating the quantum dot-formed surface according to the present invention, the laser irradiation is performed by using the sequential irradiation or the superimposed irradiation to arrange the quantum dots into the two-dimensional pattern.

In the method for fabricating the quantum dot-formed surface according to the present invention, the laser irradiation is performed while the quantum dots to be formed on the surface of the solid material fixed in the electron microscope in which a laser generator has been built-in are being observed in situ.

In the method for fabricating the quantum dot-formed surface according to the present invention, the laser irradiation is performed in the atmosphere by using the laser oscillator-integrated optical and sample-fixing platen.

The quantum dot-formed surface structure according to the present invention is one in which the periodic arrays of the plurality of quantum dots are formed on the surface of the solid material by irradiating at least one batch of laser onto the surface, and the arrays include a linear or curved sequence of the quantum dots in which the peak-to-peak distance of the plurality of quantum dots is shorter than the wavelength of the laser used in the laser irradiation.

In the method for fabricating a quantum dot-formed surface according to the present invention, the arrays include a plurality of linear sequences of the quantum dots in each of which the peak-to-peak distance of the plurality of quantum dots is shorter than the wavelength of the laser, and in the adjacent sequences, the distance between the peaks of the quantum dots each forming the sequence is longer than the peak-to-peak distance within the single sequence.

In the quantum dot-formed surface structure according to the present invention, the distance is within an error range of 10% or less with respect to the wavelength, and the peak-to-peak distance is ¼ to ⅕ times the wavelength.

Herein, the expression of “an error range of 10% or less with respect to the wavelength” means that d is within a range of 0.9λ to 1.1λ when the wavelength is indicated by λ and the distance by d.

In the quantum dot-formed surface structure according to the present invention, the curved sequence forms a circular line.

In the quantum dot-formed surface structure according to the present invention, the crystal having striped undulations which is constructed of the quantum dots being aligned with each other undergoes the epitaxial growth from the surface that is the foundation.

Hereinafter, specific results of the research will be described with reference to the accompanying views.

A state of surface quantum dot pattern arrays formed by irradiating nanosecond pulse laser onto the surface of a semiconductor was observed from the normal line direction of the surface by using a field emission-scanning electron microscope (FE-SEM), the surface being the (100) surface of single crystal Si.

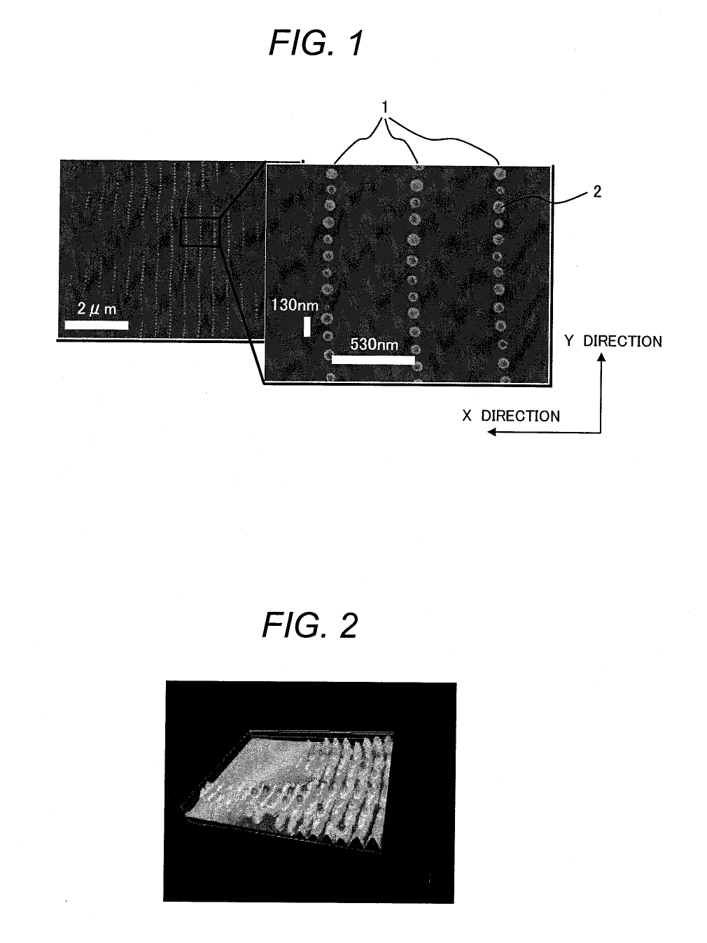

FIG. 1 illustrates a result thereof.

The pulse laser was irradiated in the atmosphere and under the conditions of 2.5×10³ J/m²/pulse, 2 Hz, 500 pulses, and the wavelength of the laser of 532 nm.

In this view, ripple pattern sequences 1 are formed in the vertical direction (Y direction) of the view, with an interval approximately the same as the wavelength being formed. Each of the ripple pattern sequences 1 is formed by surface quantum dots 2 being aligned with each other. The interval between the ripple pattern sequences 1 is 530 nm in the horizontal direction (X direction) of the view. The surface quantum dots 2 are periodically arrayed with the interval between them of 100 to 130 nm. This structure has been discovered for the first time in this research.

That is, the surface quantum dots 2 (quantum dots) form periodic arrays. A structure on the surface having the periodic arrays is referred to as a quantum dot-formed surface structure.

FIG. 2 is a perspective view illustrating a result of an atomic force microscope (AFM) measurement of the quantum dots in FIG. 1.

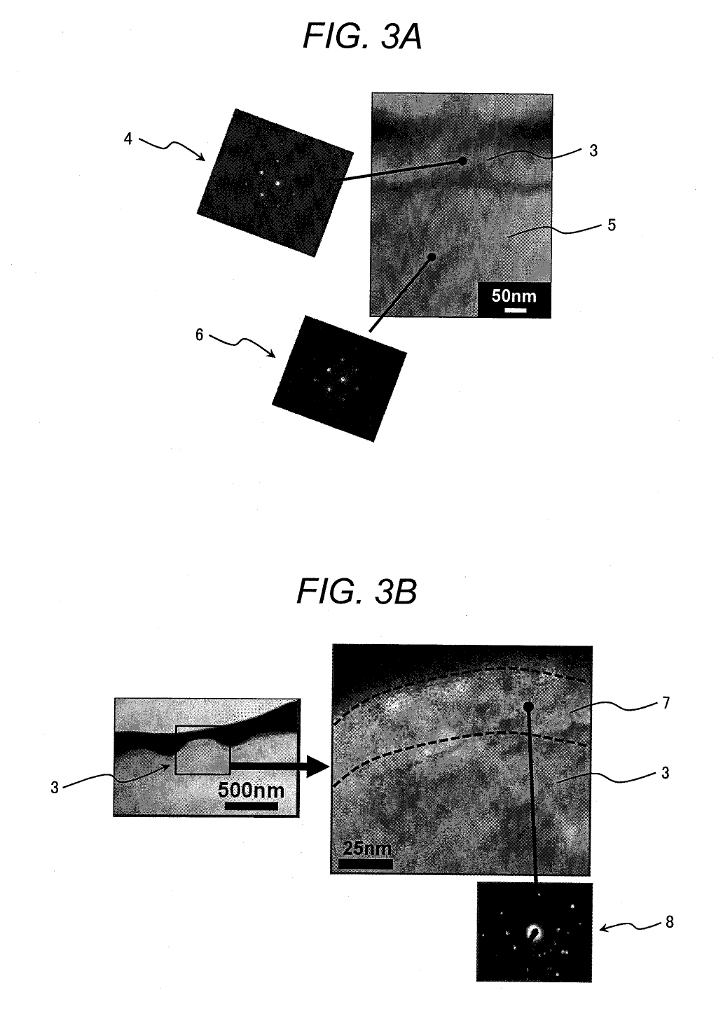

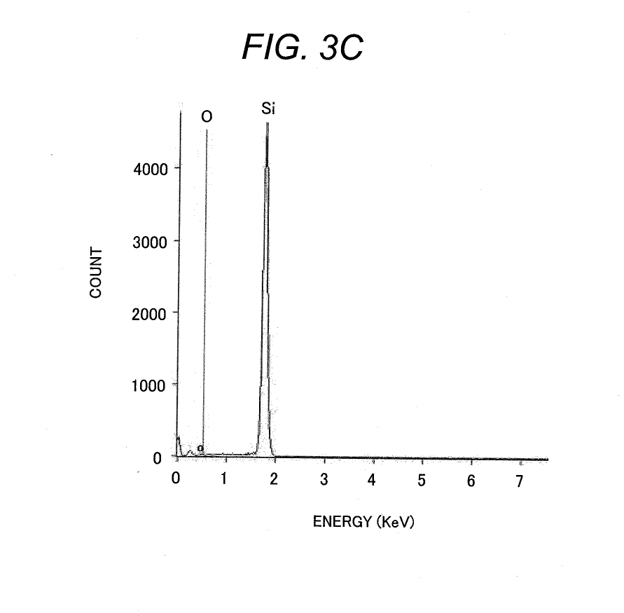

FIG. 3A illustrates a result of observing the section of the quantum dot with a TEM, taken along the Y direction illustrated in FIG. 1. FIG. 3B illustrates a result of observing the section thereof with the TEM, taken along the X direction illustrated in FIG. 1.

It is found from FIG. 2 that the quantum dots have protruded from the surface (approximately 50 nm to 100 nm) to be aligned perpendicularly with the polarization (electric field) of the linearly-polarized laser. As stated above, the ripple pattern sequences are arrayed into a linear or wave shape with an interval whose width is approximately the same as the wavelength (532 nm); however, the interval between the aligned quantum dots within the ripple pattern sequence was constant to be ¼ to ⅕ times the wavelength (approximately 100 to 130 nm).

As found from the electron-diffraction figure in FIG. 3A, the quantum dots 3 have undergone crystallization such that the crystal orientation 4 thereof is the same as the crystal orientation 6 of a substrate 5. That is, the quantum dot 3 has grown in the (100) direction. In addition, the quantum dot 3 has an elevated shape (FIG. 3A and the left of FIG. 3B) whose outermost surface has a flat area.

Additionally, as illustrated in the right of FIG. 3B (an enlarged sectional view of the tip of the quantum dot), when the quantum dot grew such that the height thereof exceeded 100 nm, the surface area of the quantum dot 3 (quantum dot surface area 7) which is originally composed of single crystal Si has involved a structure having microcrystal Si (electron diffraction pattern 8).

FIG. 3 C illustrates an EDX analysis result of the quantum dot surface area 7 (microcrystal assembly area) in FIG. 3B.

It is found from this view that the quantum dot (quantum dot surface area 7 in FIG. 3B) has not been oxidized regardless of the fact that the quantum dot was formed in the atmosphere because peaks excluding that of Si and including that of oxygen (O) cannot be observed.

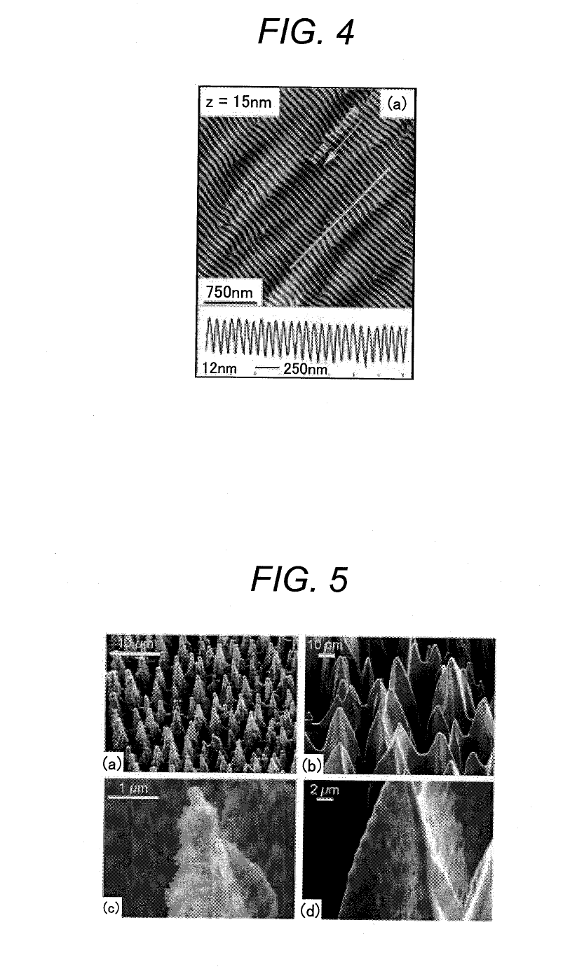

FIGS. 4 and 5 illustrate comparative examples.

FIG. 4 illustrates an example cited from Non-Patent Document 2.

This view is an AFM image illustrating a ripple pattern formed on the surface of Si irradiated with Xe⁺ ion, which also illustrates a result of measurement of a modulated shape formed on the same surface. Herein, the accelerating voltage at the ion irradiation was 2 KeV and the irradiation amount of the ion was 6.7×10¹⁸ cm⁻².

It is found from this view that a ripple pattern is generated even by ion irradiation. However, the formation and array of quantum dots have not been observed.

FIG. 5 illustrates an example cited from Non-Patent Document 3.

This view illustrates a surface structure of Si irradiated with a femtosecond laser and nanosecond laser.

In FIGS. 4 and 5, frog-shaped protrusion-depression structures are irregularly formed. These are not the surface structures in each of which quantum dots have been arrayed.

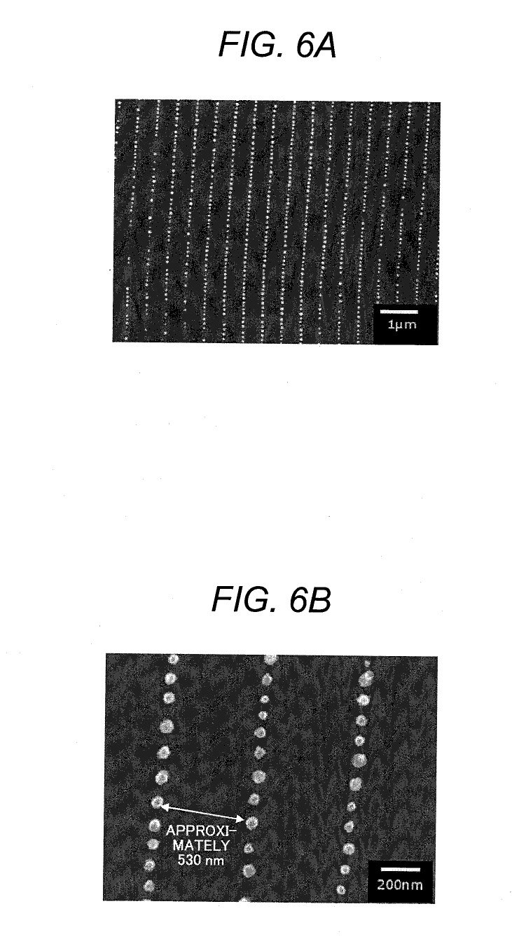

FIG. 6A is an SEM image illustrating surface dot arrays generated on the (100) surface of Si when the nanosecond pulse laser has been irradiated in the atmosphere under the conditions different from those in FIG. 1. FIG. 6B illustrates part of FIG. 6A that has been enlarged.

The pulse laser was irradiated under the conditions of 100 mJ/pulse (3.5×10³ J/m²/pulse), 2 Hz, and 2000 pulses. The dots were arrayed within a range of approximately 100 μm to 1000 μm. The diameter of the laser beam was 6 mmΦ in this case. It is known that the interval between the linear dot arrays is approximately the same as the wavelength of the laser.

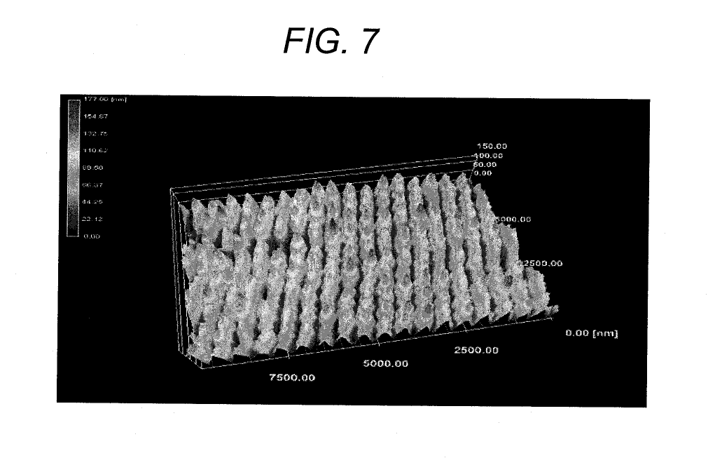

FIG. 7 is an atomic force microscope (AFM) image illustrating the surface dot arrays in FIGS. 6A and 6B.

It is found from this view that the interval between the dots within a linear array line of the dots is approximately 100 nm and surface undulations each having a height of approximately 50 to 100 nm have been generated.

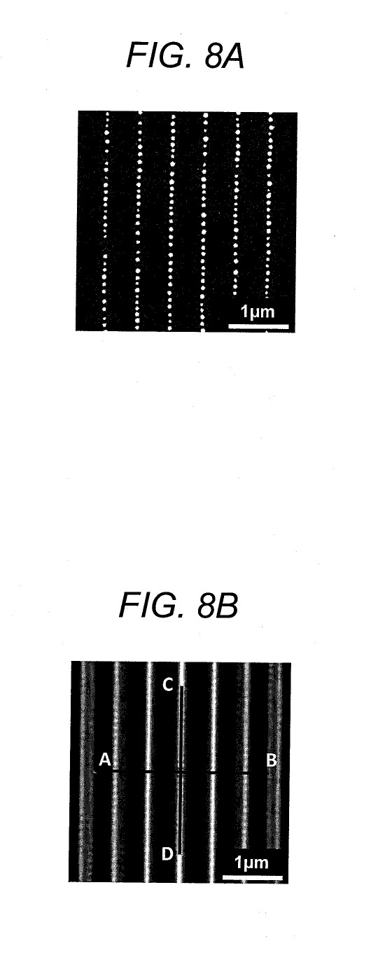

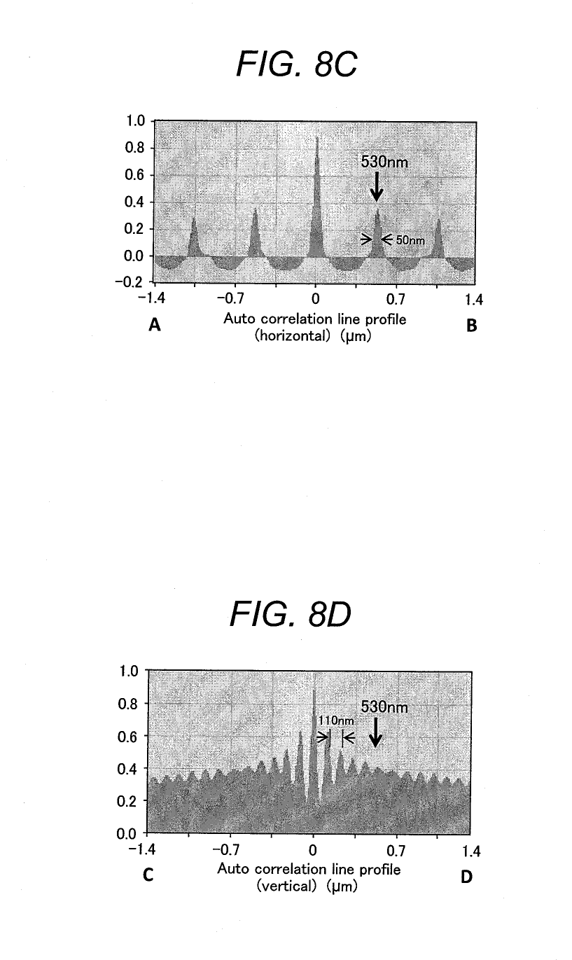

FIGS. 8A to 8D illustrate results of subjecting the pattern periodic structures to Fourier transform analysis by using the SEM images (FIGS. 6A and 6B) illustrating the surface dot arrays formed with the laser irradiation.

FIG. 8A is an SEM image illustrating surface dot arrays formed with the laser irradiation. FIG. 8B is an autocorrelation image created by Fourier transform from FIG. 8A. FIG. 8C illustrates the line intensity profile, taken along Line A-B illustrated in FIG. 8B, while FIG. 8D illustrates the line intensity profile, taken along Line C-D illustrated in FIG. 8B.

It is found from these views that the ripple average periodic interval is 530 nm and the error is within 10% or less with respect to the half-width of the intensity peak of 50 nm. Also, it can be identified that the dot average interval is approximately 110 nm, which is equal to ¼ to ⅕ times the wavelength (100 to 130 nm).

Subsequently, an elementary process of forming the surface dots was observed in situ by irradiating the nanosecond pulse laser onto the (100) surface of Si in vacuum (within the ultrahigh voltage electron microscope) and under the conditions of 4.3×10² J/m²/pulse, 2 Hz, and up to 140 pulses.

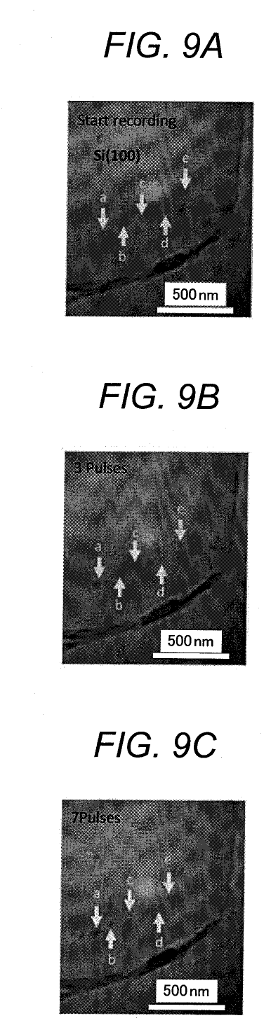

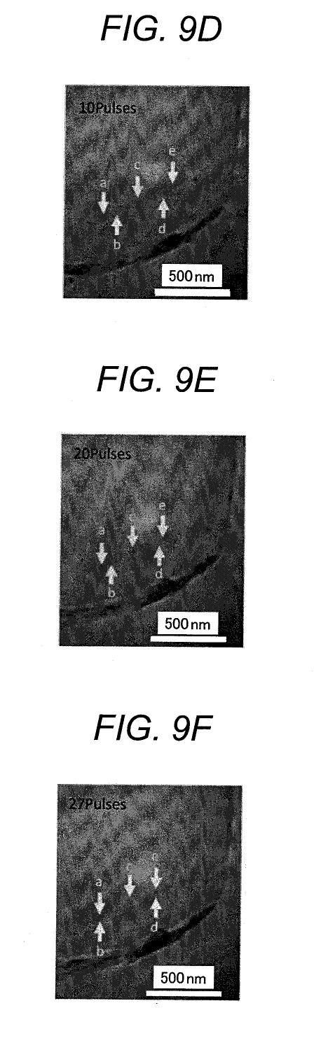

FIGS. 9A to 9F illustrate results thereof.

FIGS. 9A, 9B, 9C, 9D, 9E and 9F illustrate the states at the beginning of the irradiation and after 3 pulses, 7 pulses, 10 pulses, 20 pulses and 27 pulses, respectively.

A process is found from these views, in which the surface of a sample is first chipped off such that small dots are generated, and the dots then diffuses on the surface and are aligned into one sequence while one dot absorbing another. This phenomenon has been confirmed for the first time by this experiment.

It has been proved from this experiment that the surface dots formed with laser irradiation are arrayed due to the “self-organization”. Herein, the “self-organization” means that an atomic cluster (debris) which has been desorbed from the surface (the excitation effect by the ablation) with the pulse laser irradiation (top-down method), continues to undergo the dot growth by a bottom up from the substrate, while spreading on the surface by the subsequent irradiation and the thermal effect due to the irradiation (as illustrated in the in-situ result in FIG. 9), so that the dots are arrayed at constant intervals (organized).

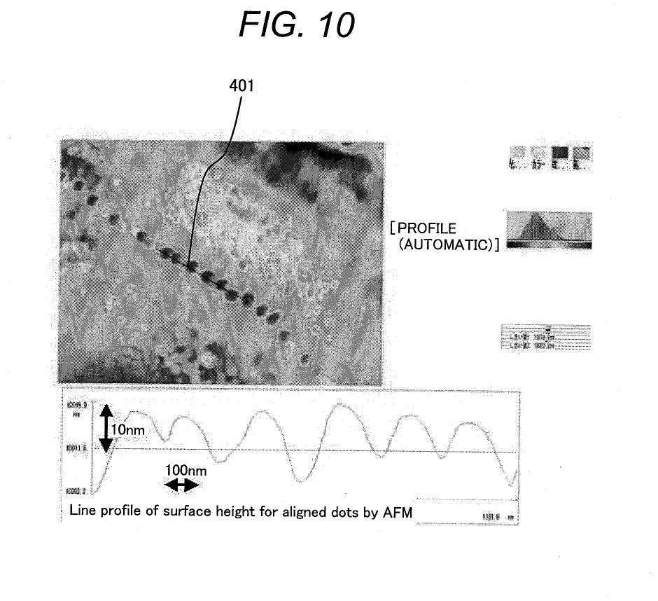

FIG. 10 illustrates a result of AFM measurement of a line profile of the surface dot sequence formed under the conditions described with respect to FIGS. 9A to 9F. The section whose line profile has been measured is indicated by Reference Numeral 401.

It is found from this view that the dots are arrayed such that the height thereof is 10 to 20 nm and the period is 100 to 130 nm.

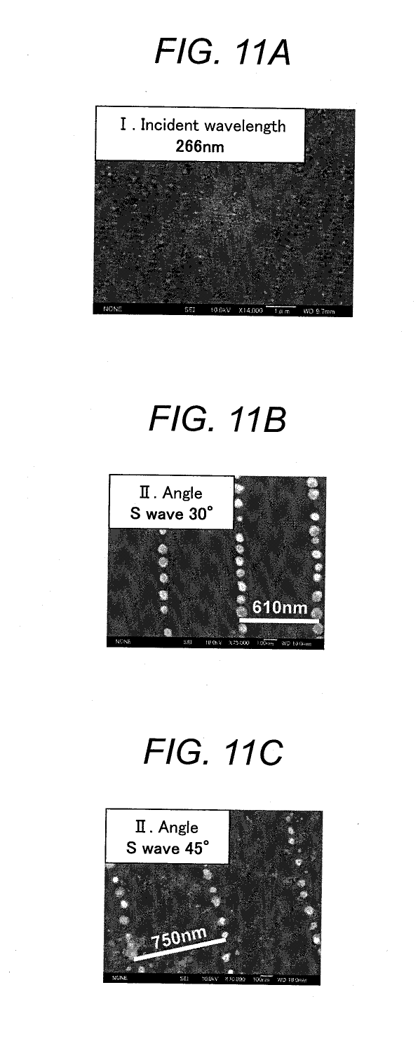

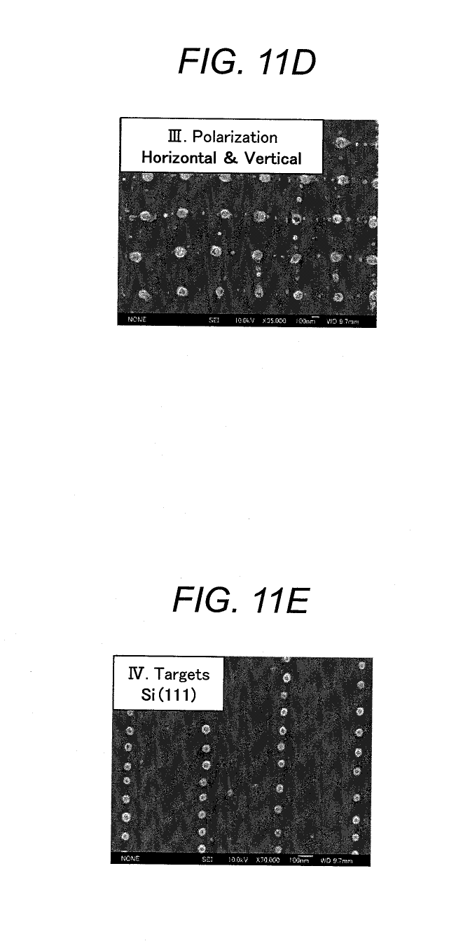

FIGS. 11A to 11E summarize results of the experiment of parameters (wavelength, inclination, polarization and plane orientation) with respect to the controllability of a quantum dot pattern.

As illustrated in FIG. 11A, the quantum dot pattern is dependent on the incident wavelength of the laser beam. A ripple periodic interval is proportional to the incident wavelength of the laser to be used. That is, it is found that the ripples can be arrayed at an interval of 266 nm as illustrated in FIG. 11A, in addition to at an interval of 532 nm illustrated in FIGS. 1, 6A and 6B, and that the quantum dots can be arrayed within the ripple.

FIGS. 11B and 11C summarize an influence by the angle of the laser beam with respect to a sample. The pattern of the quantum dots was changed by an S-wave or P-wave and by the angle of the polarization plane with respect to the surface of the sample.

In the case of an S-wave, the interval of the ripples Λ=λ(1±sin θ) or Λ=λ/cos θ, and hence Λ is dependent on an inclined angle θ. Herein, the inclined angle θ is the angle formed by the incident line of the laser on a sample and the normal line of the surface of the sample. In the case where the wavelength of the laser used in the experiment is 532 nm, theoretical values of Λ are: Λ=355 nm or 1064 nm when θ=30°, Λ=752 nm when θ=45°, and Λ=1064 nm when θ=60°.

The example in FIG. 11B illustrates a result of fabricating a ripple pattern sequence in which, when θ=30°, Λ=λ/cos θ=610 nm. The example in FIG. 11C illustrates a result of fabricating a ripple pattern sequence in which, when θ=45°, Λ=750 nm. These ripple pattern sequences are examples that can be formed by controlling the quantum dots.

FIG. 11D illustrates an example in which the pattern of the quantum dots can be controlled with the polarization of the laser beam being a parameter.

The quantum dot sequences (ripple) are arrayed to be perpendicular to the polarization (electric field) of the laser. Accordingly, when the irradiation is performed with the polarization plane being rotated by the polarizing plate, the ripple is rotated with the rotation. When the superimposed irradiation is performed by using this operation, it becomes possible to fabricate an arbitrary surface pattern. The example in FIG. 11D is obtained by performing superimposed irradiation with the polarization being rotated 90°, and it is found that quantum dot sequences can be formed to intersect perpendicularly with each other.

FIG. 11E illustrates a result of checking the plane orientation dependence of a target material to be irradiated with the laser.

The target material is single crystal Si, and the (100) surface of Si was used in FIGS. 1, 6A, and 6B. In the (111) surface of Si illustrated in FIG. 11E and another plane orientation thereof, the modes of the formed dots were not different from that in the (100) surface.

It has first been found from the research of the present invention that the plurality of quantum dots can be simultaneously formed on the surface of the material with the laser irradiation.

As stated above, it has been made clear that the formed patterns of the quantum dots can be freely controlled by combinations of the wavelength, inclination and polarization.

Hereinafter, examples in which the best embodiments according to the present invention are exemplified will be described.

### Example 1

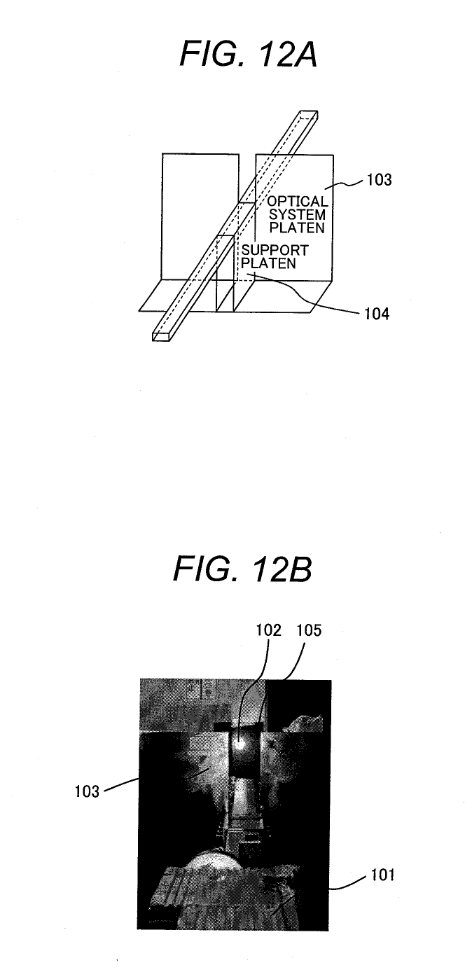

FIG. 12A is a schematic perspective view illustrating a stand apparatus for a laser irradiation used in tests of a laser irradiation in the atmosphere, and FIG. 12B is a photograph illustrating the apparatus during the laser irradiation test.

In the laser oscillator-integrated optical and sample-fixing platen (the schematic perspective view of FIG. 12A), a laser transmitter 101, a sample 105 and an optical system platen 103 were fixed to a support platen 104 to synchronize these vibrations with each other, taking a vibration isolation into consideration.

The photograph of FIG. 12B illustrates a state where the laser beam transmitted from the laser transmitter 101 has reached the sample 105 such that the irradiated area 102 in the sample 105 is shining. It can also be recognized from the photograph that laser is being irradiated through a slit provided in the optical system platen 103.

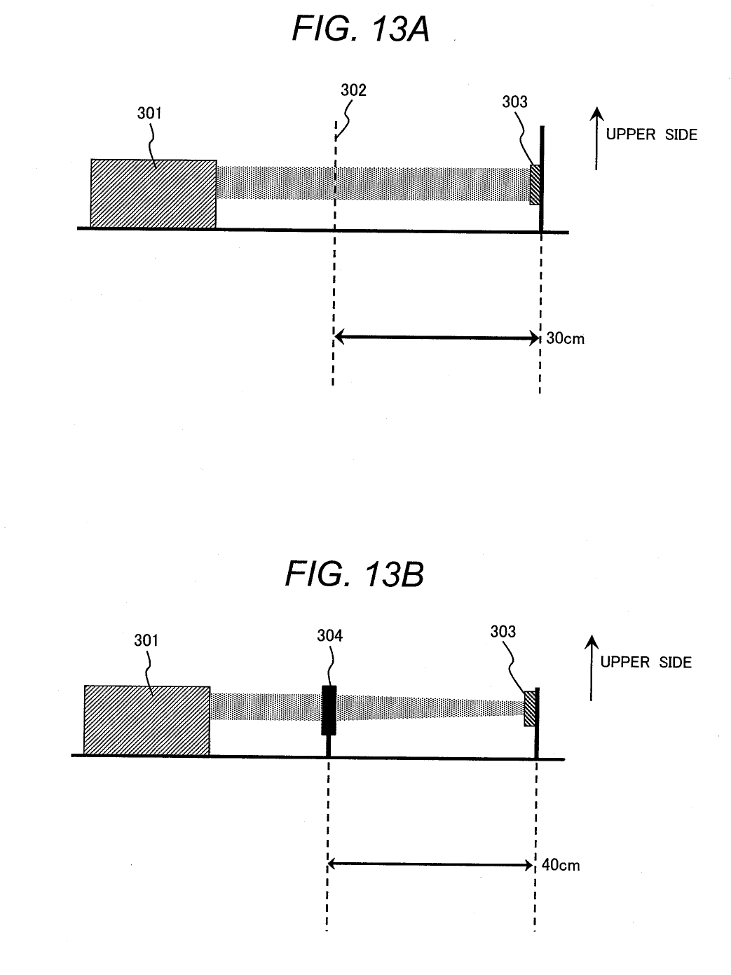

FIG. 13A is a schematic view illustrating a laser irradiation system (an irradiation system according to the present example), while FIG. 13B is a schematic view illustrating an irradiation system for irradiating the laser by colleting it with a lens (an irradiation system according to a comparative example).

In FIG. 13A, it is made that a laser 305 is irradiated toward a sample 303 via an optical system platen 302 from a laser transmitter 301.

In FIG. 13B, it is made that the laser 305 is irradiated toward the sample 303 via a collecting lens 304 from the laser transmitter 301.

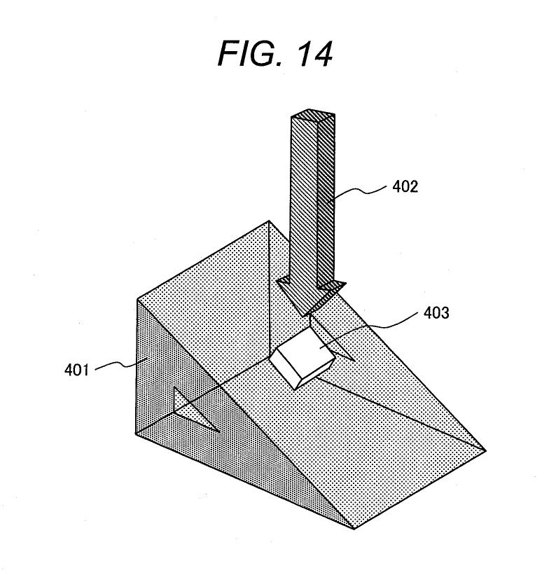

FIG. 14 is a schematic view illustrating a laser irradiation-inclining table used for inclining a laser beam.

An inclining table 401 is made of acrylic, and configured such that a sample 403 is fixed to the inclined plane of the inclined table 401 to irradiate a laser beam 402 onto the sample 403.

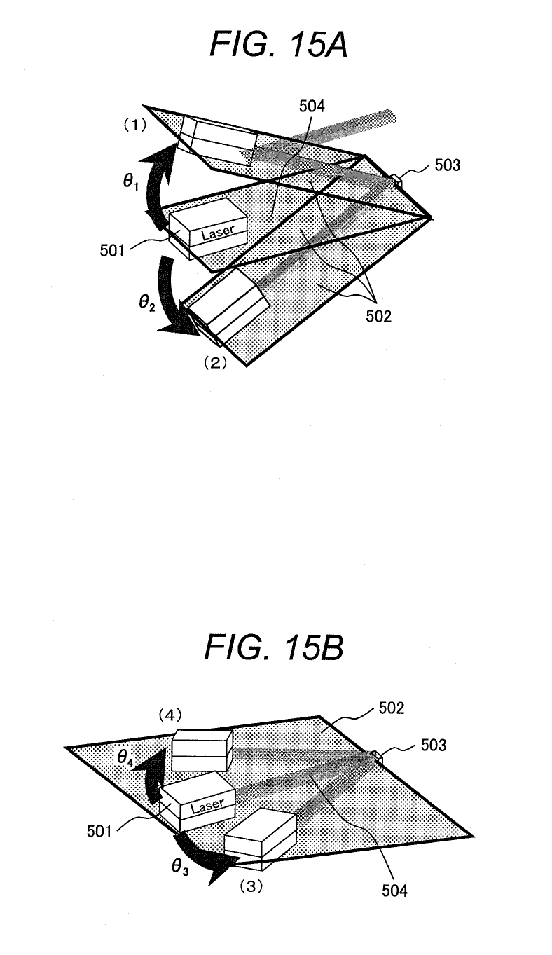

FIGS. 15A and 15B are schematic views each illustrating a state of irradiating an inclined laser.

FIG. 15A illustrates the case of a P-wave, while

FIG. 15B illustrates the case of an S-wave.

In these views, a laser transmitter 501 and a polarizing plate 502 are integrated with each other to be rotatable around a sample 503. Accordingly, it is made that a laser beam 504 can be irradiated onto a sample 503 even when the laser transmitter 501 and the polarizing plate 502 are rotated.

FIG. 15A illustrates the case where the angle of the laser beam 504 is changed in the vertical direction, and the case where the angle is changed upward by θ₁ is indicated by polarization (1) and the case where the angle is changed downward by θ₂ is indicated by polarization (2).

FIG. 15B illustrates the case where the angle of the laser beam 504 is changed in the horizontal direction, and the case where the angle is changed counterclockwise by θ₃ viewed from upper side is indicated by polarization (3) and the case where the angle is changed clockwise by θ₄ viewed from upper side is indicated by polarization (4).

A plurality of quantum dot patterns were formed by using this apparatus.

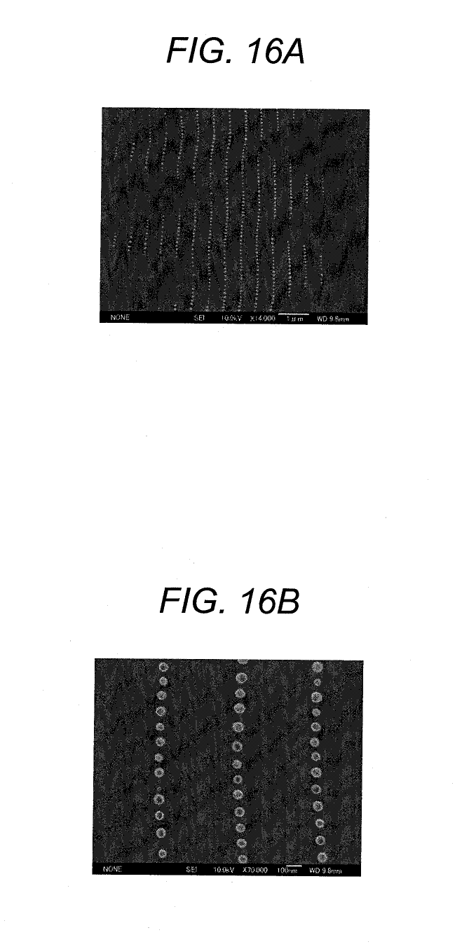

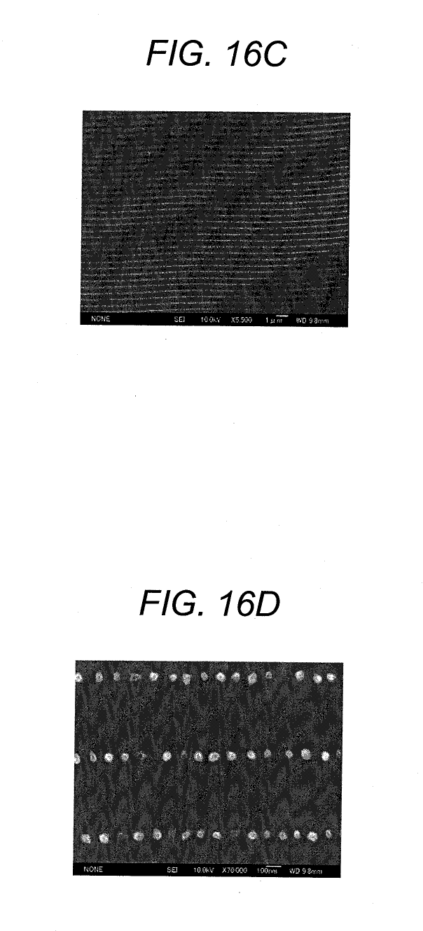

An example of a quantum dot array in which a pattern of a quantum dot sequence has been rotated by 90° by rotating the polarization by 90° will be first illustrated in FIG. 16.

Each of FIGS. 16A and 16B illustrates a quantum dot array pattern formed on the (100) surface of single crystal Si when the nanosecond pulse laser has been irradiated onto the surface in the atmosphere and under the conditions of a wavelength of 532 nm, horizontal polarization, 2.5×10³ J/m²/pulse, 2 Hz, and the pulse number of 500 pulses by using Laser Inlite II. FIG. 16B illustrates part of FIG. 16A that has been enlarged.

In these views, ripple pattern sequences are formed in each of which quantum dots are aligned with each other in the vertical direction. The ripple pattern sequences have been simultaneously formed.

Each of FIGS. 16C and 16D illustrates a quantum dot array pattern formed on the (100) surface of single crystal Si that is completely the same as that in FIGS. 16A and 16B when the nanosecond pulse laser has been irradiated onto the surface in the atmosphere and under the conditions of a wavelength of 532 nm, 90° polarization, 3.5×10³ J/m²/pulse, 2 Hz, and the pulse number of 1000 pulses by using the same laser apparatus. FIG. 16D illustrates part of FIG. 16C that has been enlarged.

Comparing FIGS. 16C and 16D with FIGS. 16A and 16B, the ripple pattern sequences are formed in each of which quantum dots are aligned with each other in the horizontal direction that has been made by the vertical direction being rotated by just 90°. The ripple pattern sequences have also been simultaneously formed.

### Example 2

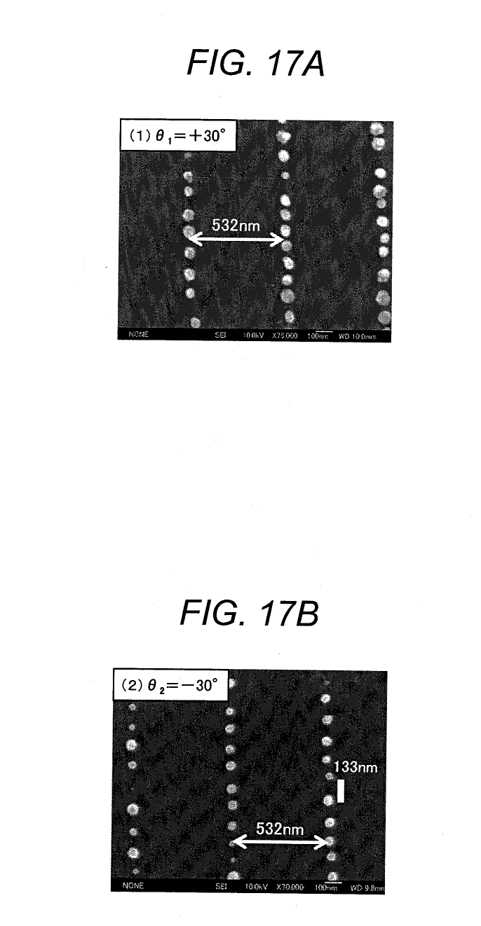

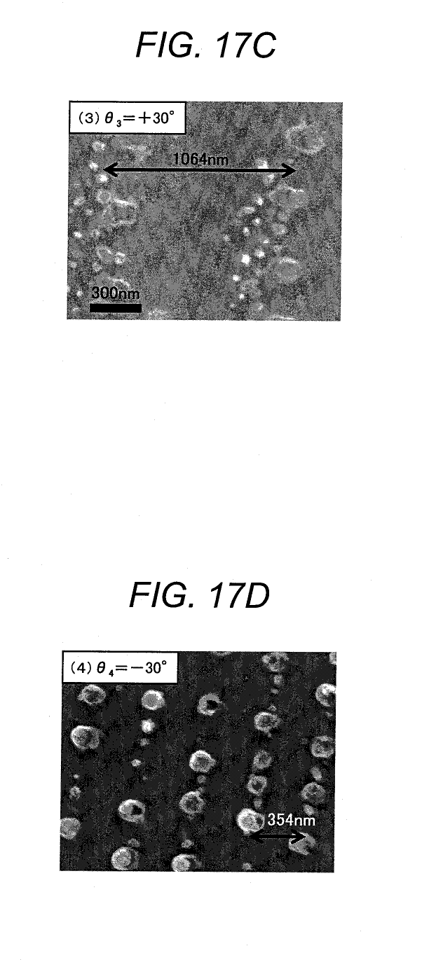

Each of FIGS. 17A and 17D illustrates an example in which a two-dimensional pattern of quantum dots has been formed on the (100) surface of single crystal Si when the nanosecond pulse laser has been irradiated onto the surface in the atmosphere and under the conditions of 2.5×10³ J/m²/pulse, 2 Hz, the pulse number of 500 pulses, and the polarizations (1) to (4) illustrated in FIGS. 15A and 15B by using Laser Inlite II (wavelength: 532 nm). Polarization angles are set as follows: with respect to a P-wave, θ₁=+30° (Polarization (1)), θ₂=−30° (Polarization (2)); and with respect to an S-wave, θ₃=+30° (Polarization (3)), θ₄=−30° (Polarization (4)).

In any one of the cases, patterns were able to be simultaneously formed in each of which a plurality of quantum dots were arrayed.

### Example 3

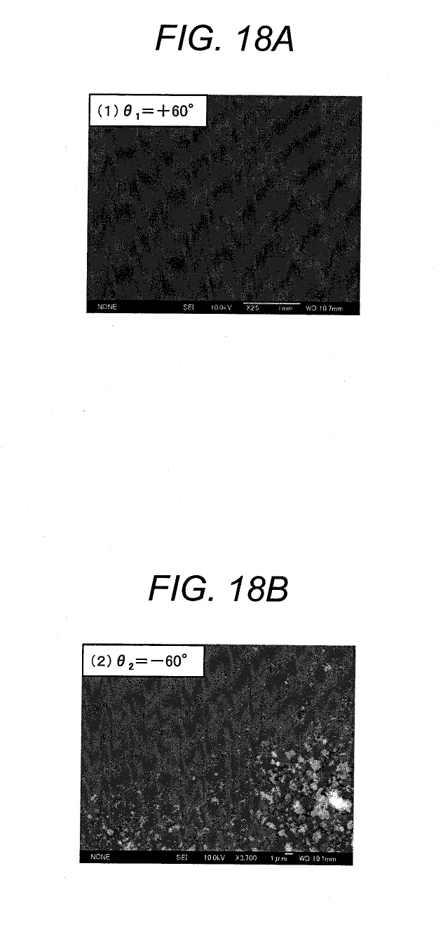

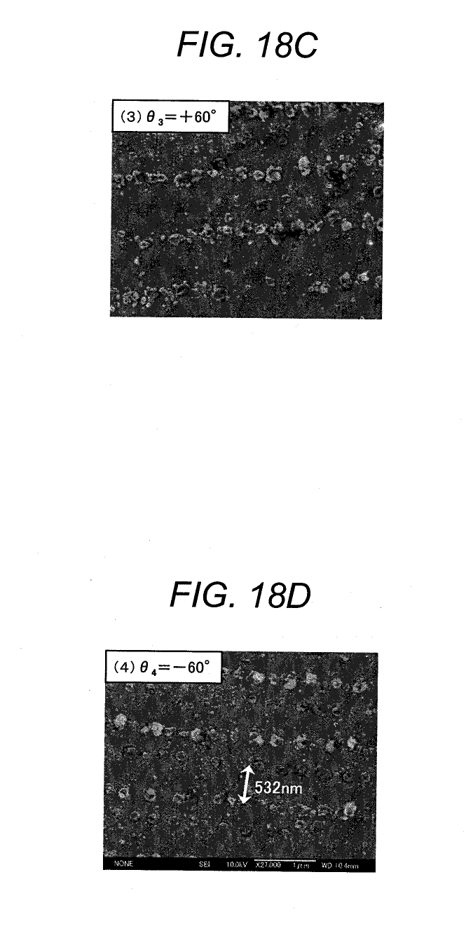

Each of FIGS. 18A to 18D illustrates an example in which a two-dimensional pattern of quantum dots has been formed on the (100) surface of single crystal Si when the nanosecond pulse laser has been irradiated onto the surface in the atmosphere and under the conditions of 2.5×10³ J/m²/pulse, 2 Hz, the pulse number of 500 pulses, and the polarizations (1) to (4) illustrated in FIGS. 15A and 15B by using Laser Inlite II (wavelength: 532 nm). Polarization angles are set as follows: with respect to a P-wave, θ₁=+60° (Polarization (1)), θ₂=−60° (Polarization (2)); and with respect to an S-wave, θ₃=+60° (Polarization (3)), θ₄=−60° (Polarization (4)).

In the case of an S-wave, patterns were able to be simultaneously formed in each of which a plurality of quantum dots were arrayed.

However, in the case of a P-wave, a pattern in which quantum dots were arrayed was not able to be formed. Accordingly, in the case of a P-wave, the laser was irradiated under the conditions according to the comparative example.

### Example 4

In Example 1 illustrated in FIGS. 16A and 16B, a quantum dot array pattern has been formed by irradiating the nanosecond pulse laser onto the (100) surface of single crystal Si in the atmosphere and under the conditions of a wavelength of 532 nm, horizontal polarization, 2.5×10³ J/m²/pulse, 2 Hz, and the pulse number of 500 pulses by using Laser Inlite II.

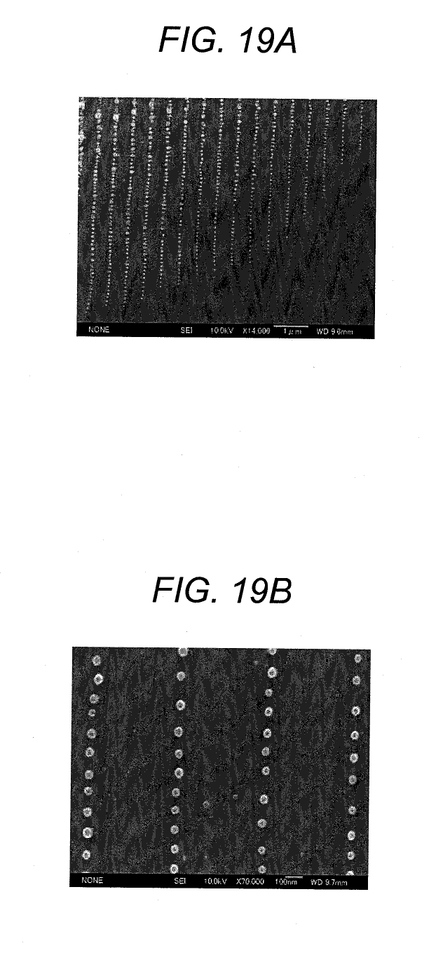

On the other hand, FIGS. 19A and 19B (the present example) illustrate a quantum dot array pattern formed on the (111) surface of single crystal Si to which has been changed when the laser has been irradiated onto the surface in the atmosphere and under the conditions of a wavelength of 532 nm, horizontal polarization, 3.5×10³ J/m²/pulse, 2 Hz, and the pulse number of 2000 pulses by using Laser Inlite II. FIG. 19B illustrates part of FIG. 19A that has been enlarged.

Also, in the present example, ripple pattern sequences were able to be simultaneously formed in each of which quantum dots were aligned with each other in the vertical direction, as in Example 1 illustrated in FIGS. 16A and 16B.

The present example illustrates the case where the direction in which quantum dots are aligned with each other can be determined independently of a crystal orientation of an irradiated material.

Examples 5 to 8 described hereinafter will show that sequences formed with quantum dots (ripple patterns) can be arranged into various two-dimensional pattern shapes by using a fabricating method according to the present invention.

### Example 5

Quantum dot sequences were first formed on the (100) surface of single crystal Si in the vertical direction by irradiating the nanosecond pulse laser onto the surface in the atmosphere and under the conditions of a wavelength of 532 nm, an inclined angle of θ (angle formed by the incident line of the laser on a sample and the normal line of the surface of the sample)=0° (i.e., the laser was perpendicularly incident on the surface of the sample), horizontal polarization, 2.5×10³ J/m²/pulse, 2 Hz, and the pulse number of 1000 pulses with the use of Laser Inlite II. Subsequently, the polarization was rotated by 90° with a polarizer such that superimposed irradiation was performed on the same place of the sample under the same conditions.

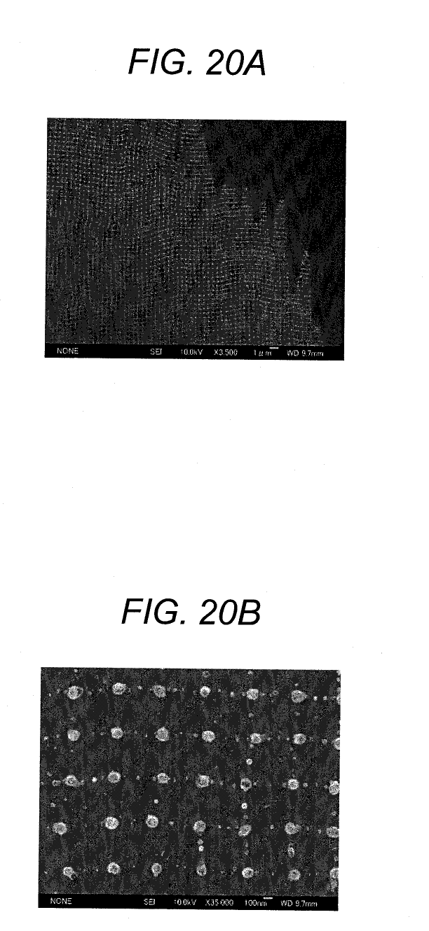

As a result, a quantum dot-formed surface was able to be fabricated on the surface of Si in which periodic arrays of quantum dots were arranged into a two-dimensional pattern having a square shape, as illustrated in FIGS. 20A and 20B.

FIG. 20B illustrates part of FIG. 20A that has been enlarged.

### Example 6

Quantum dot sequences were first formed on the (100) surface of single crystal Si in the vertical direction by irradiating nanosecond pulse laser onto the surface in the atmosphere and under the conditions of a wavelength of 532 nm, an inclined angle of θ=0°, horizontal polarization, 2.5×10³ J/m²/pulse, 2 Hz, and the pulse number of 1000 pulses with the use of Laser Inlite II. Subsequently, the polarization was rotated by 45° with the polarizer such that the superimposed irradiation was performed on the same place of the sample under the same conditions.

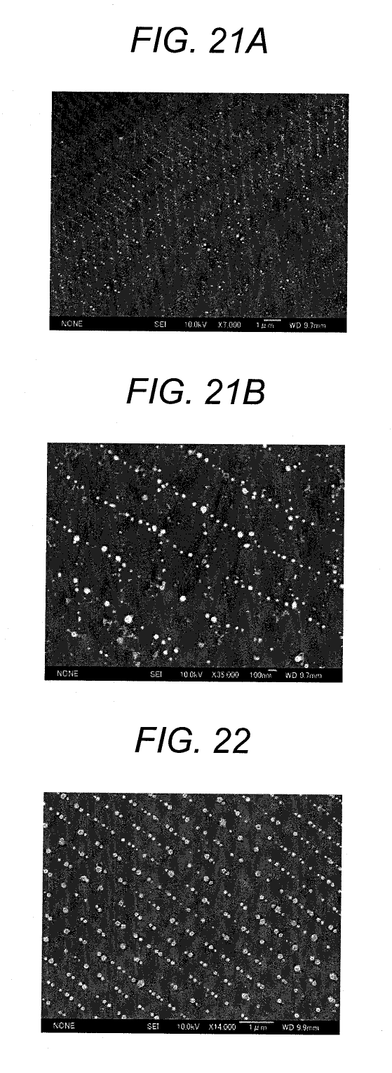

As a result, a quantum dot-formed surface was able to be fabricated on the surface of Si in which periodic arrays of quantum dots were arranged into a two-dimensional pattern having a diamond shape, as illustrated in FIGS. 21A and 21B.

FIG. 21B illustrates part of FIG. 21A that has been enlarged.

### Example 7

Quantum dot sequences were first formed on the (100) surface of single crystal Si in the vertical direction by irradiating the nanosecond pulse laser onto the surface in the atmosphere and under the conditions of a wavelength of 532 nm, an inclined angle of θ=0°, horizontal polarization, 2.5×10³ J/m²/pulse, 2 Hz, and the pulse number of 1000 pulses with the use of Laser Inlite II. Subsequently, the polarization was rotated by 53° with the polarizer such that the superimposed irradiation was performed on the same place of the sample under the same conditions.

As a result, a quantum dot-formed surface having a two-dimensional pattern in which large and small dots existing in a mixed manner was able to be fabricated on the surface of Si.

Because the angle of 53° by which the polarization is rotated is one of angles of a right triangle having a ratio of three sides of 3:4:5, an arrangement (a right triangle having two sides of 3 times and 4 times of a dot period; and oblique side of 5 times the dot period) in which a dot periodic interval matches the wavelength period (4 times the dot period) exists by using a ¼ times-component of the dot period (¼ to ⅕ times the wavelength). Thereby, it is possible to make a dot grow large in size at the position where the dot to grow in the previous irradiation and that to grow in the subsequent irradiation overlap each other at the superimposed irradiation.

It is observed in this view that sequences including large dots at the relevant positions have been diagonally formed and small dots have been formed at other positions.

### Example 8

Quantum dot sequences were first formed in the vertical direction on the (100) surface of single crystal Si by irradiating nanosecond pulse laser onto the surface in the atmosphere and under the conditions of a wavelength of 532 nm, an inclined angle of θ=0°, horizontal polarization, 2.5×10³ J/m²/pulse, 2 Hz, and the pulse number of 1000 pulses with the use of Laser Inlite II. Subsequently, the polarization was rotated by 37° with the polarizer such that the superimposed irradiation was performed on the same place of the sample under the same conditions.

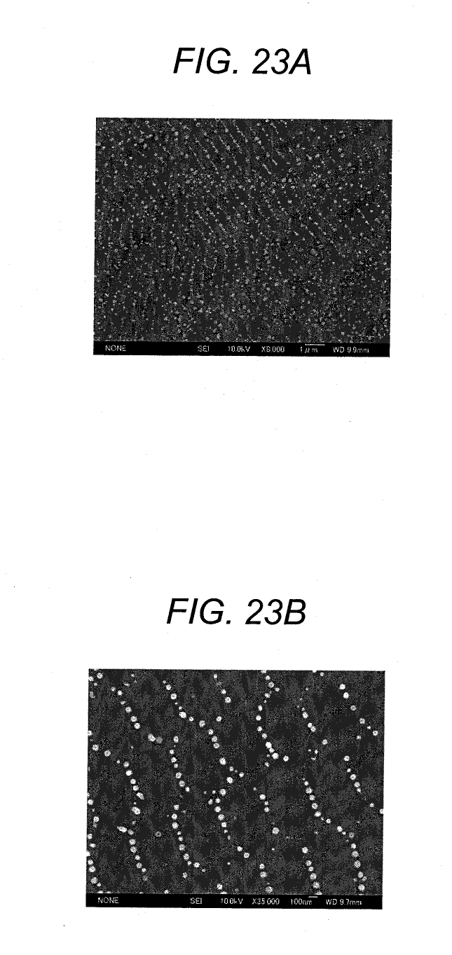

As a result, a quantum dot-formed surface was able to be fabricated on the surface of Si in which periodic arrays of quantum dots were arranged into a two-dimensional pattern having a honeycomb structure, as illustrated in FIGS. 23A and 23B. FIG. 23B illustrates part of FIG. 23A that has been enlarged.

In the case of such an intermediate angle, vertical dot sequences (first irradiation) and horizontal dot sequences (later irradiation) exist in a mixed manner. That is, a circular or polygonal array can be induced by a self organization of the dots.

Each of above Examples 5 to 8 shows the case where quantum dots are aligned with each other in the vertical direction by the irradiation of the linearly-polarized pulse laser (horizontal polarization) and then the superimposed irradiation is sequentially performed by appropriately changing the angle with the polarizer.

These examples show various patterns of quantum dot sequences, each of the patterns being obtained during a process where a quantum dot two-dimensional array is gradually fabricated by an effect with the later irradiation with a gradual disappearance of an effect with the first irradiation.

The quantum dot two-dimensional periodic array illustrated in each of Example 5 to 8 is also generated even to in the superimposed irradiation test where the laser irradiation are simultaneously performed, other than the sequential irradiation. In this case, a two-dimensional pattern can be obtained which is a group of quantum dot sequences generated simultaneously, each of which is perpendicular to the polarization direction of each laser beam.

Such a method for fabricating quantum dot periodic arrays generated into a two-dimensional pattern by the superimposed irradiation (including a simultaneous irradiation), and the quantum dot two-dimensional periodic pattern array-formed surface structure and the various device structures obtained by this method are encompassed by a fabrication method and a device structure according to the present invention.

### Example 9

With a Zn-doped GaAs material being used as an irradiation target, the nanosecond pulse laser was irradiated in the atmosphere and under the conditions of a wavelength of 532 nm, an inclined angle of θ=0°, horizontal polarization, 100 mJ/pulse (3.5×10 J/m²/pulse), 2 Hz, and 1000 pulses with the use of Laser Inlite II.

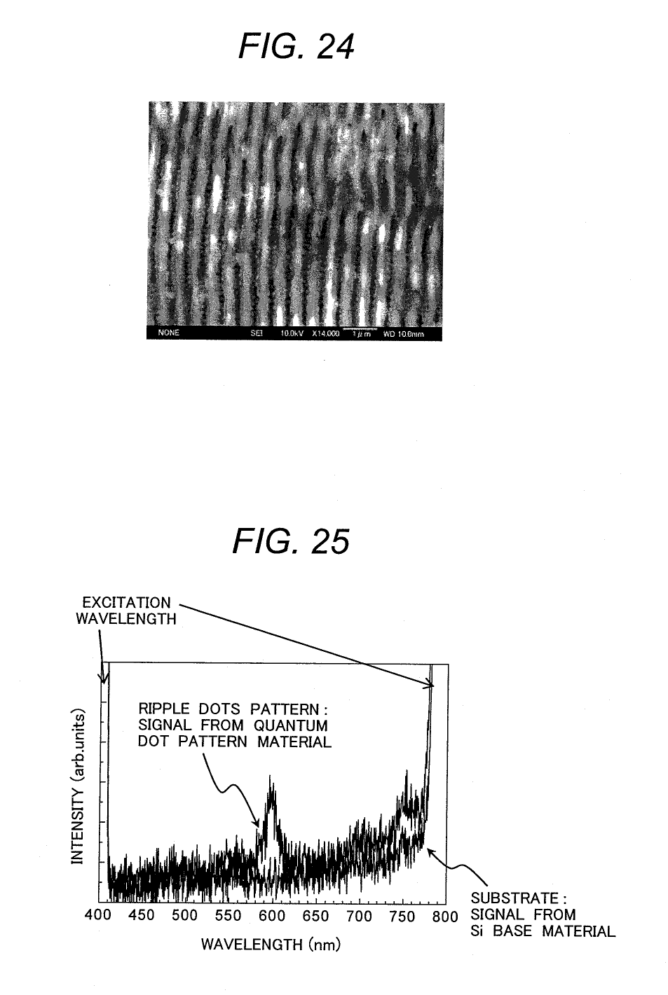

As a result, quantum dot sequences were able to be simultaneously formed in the vertical direction even on the surface of the Zn-doped GaAs material, as illustrated in FIG. 24.

### Example 10

FIG. 25 is a graph illustrating a result of measurement of photoluminescence (also referred to as PL) of a quantum dot pattern of the quantum device having the quantum dot pattern (FIGS. 6A and 6B) fabricated by a method according to the present invention, the measurement of the quantum function physical property having been performed in the quantum dot pattern.

In order not to break the quantum dot pattern illustrated in FIGS. 6A and 6B, conditions under which PL is to be measured are determined as follows: an excitation wavelength of 400 nm (second harmonic generation (SHG) of 800 nm), Ti: sapphire femtosecond pulse laser (wavelength of 800 nm), pulse width of 140 femtoseconds (fs), repetition rate of 80 MHz, and convergent beam with an objective lens: x 40 NA 0.77. PL intensity is represented along the vertical axis with a wavelength being represented along the horizontal axis.

In FIG. 25, a signal (intensity) from the quantum dot pattern material is slightly higher than a signal (intensity) from the Si base material. A very sharp signal having a half-width of approximately 20 nm was detected near 600 nm. This is a quantum dot signal of a green band from a dot surface (naturally-oxidized interface), and accordingly it has been proved that a quantum device in which the quantum dot pattern according to the present invention has been formed has a good quantum function physical property.

### Example 11

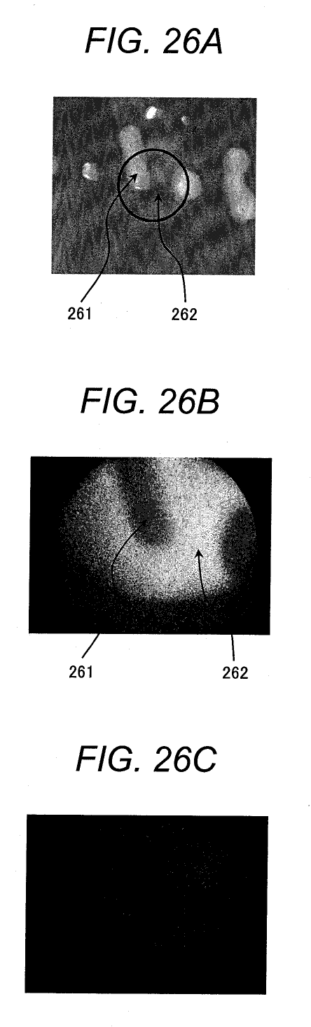

FIGS. 26A to 26C illustrate results of measurement of a quantum function surface physical property of a quantum device having a quantum dot pattern (FIGS. 6A and 6B) fabricated by the method according to the present invention. Photoelectron emission measurement (PEEM: electron emission is detected by irradiating a light) was performed for measuring a quantum function surface physical property.

FIG. 26A is an SEM image illustrating an area to be measured.

A quantum dot ripple area 261 is represented by a white contrast area, and an area 262 other than the quantum dot ripple area (another area) is represented by a gray contrast area.

FIG. 26B illustrates a result of performing PEEM measurement using ultraviolet light of 220 to 280 nm (5.6 to 4.4 eV).

In this view, photoelectron emission was not generated in the quantum dot ripple area 261 (quantum dot ripple-formed area), which made the area 261 dark.

FIG. 26C illustrates a result of performing PEEM measurement using a 220 nm (5 eV)-cut filter for cutting a short wavelength band.

In this view, it is found that a working function of the surface on an area where a laser intensity is high and a ripple pattern has been generated is different from that of the surface of an area around the above area because the whole area becomes dark. It can be considered that an area other than the area where the ripple pattern has been formed has a work function value of approximately 5.0 eV (4.4 to 5.6 eV), while the area where a quantum dot ripple area (a striped undulation area) has that of 5.6 eV or more.

It has been confirmed that a quantum device in which a quantum dot pattern according to the present invention has been formed can also be used as a catalyst device and a functional surface device having an additional surface energy (in this case, 0.5 to 1.2 eV) with this characteristic surface photoelectron property.

### Example 12

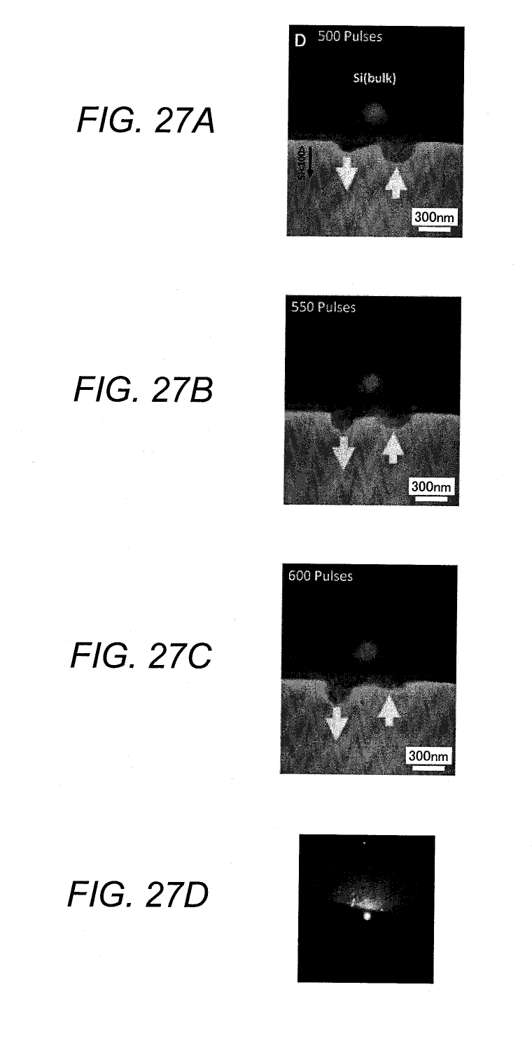

FIGS. 27A to 27C illustrate results of a TEM observation of the organization on the surface irradiated with the nanosecond pulse laser.

The laser was irradiated in vacuum and under the conditions of 25 mJ/pulse (3.5×10³ J/m²/pulse) and 2 Hz. The results were obtained by video shooting while an elementary process of forming quantum dots during 500 to 600 pulses was being continuously observed with the TEM, the process being performed within the ultrahigh voltage electron microscope. FIGS. 27A, 27B and 27C illustrate the states after 500 pulses, 550 pulses and 600 pulses, respectively.

The TEM photographs were taken with a state where a dot grew into a cone shape (300 nm) after protruding from a surface when irradiated with laser within the ultrahigh-voltage electron microscope, being laterally transmitted.

A process was photographed in which the dot on the left side grew into a cone shape and therewith the big dot on the right side contracted as the laser irradiation continued.

This result shows a process during which dots grow bigger while one dot absorbing another.

Also, a state where a black (Bragg-reflected) microcrystal area was changed every pulse on an outermost surface of the cone was simultaneously observed.

FIG. 27D is an image illustrating an electron diffraction pattern (RHEED image) taken from the cone.

It is found from this view that a cone is formed of microcrystal Si. From this, it has been made clear that the outermost surface area whose temperature has been raised due to the laser irradiation continues to grow while repeating a molten state and an instantly-coagulated state (crystallization).

A method for forming a plurality of quantum dots including such a typical elementary process of forming the quantum dots with the laser irradiation is encompassed by a method for fabricating the quantum dot formed-surface according to the present invention.

### Example 13

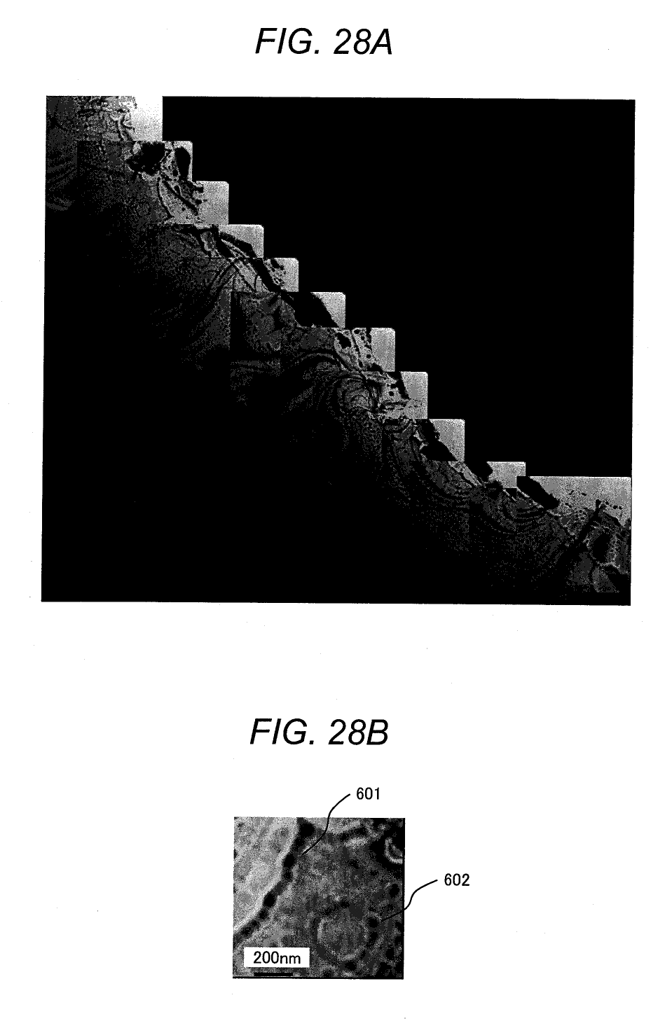

FIG. 28A is a TEM image illustrating quantum dots formed near the edge of a sample after laser had been irradiated onto the (100) surface of Si in vacuum within the ultrahigh voltage electron microscope. Nd: YAG (wavelength of 532 nm) was used. Nanosecond pulse lased was irradiated under the conditions of 2 Hz, 4.3×10² J/m²/pulse and 140 pulses.

This view illustrates a state where linear quantum dots and circular quantum dots are simultaneously to be formed, and illustrates multiple various quantum dot arrays formed near the edge of the sample, the arrays being observed within the ultrahigh voltage electron microscope.

FIG. 28B illustrates part of FIG. 28A that has been enlarged.

It can be confirmed from this view that a linear quantum dot array 601 and a circular quantum dot array 602 have been formed. These quantum dot arrays can be referred to as a periodic array. That is, the periodic array includes a linear or a curved array in which the interval between the peaks of a plurality of quantum dots is shorter than the wavelength of the irradiated laser. Herein, the “curved” includes “circular”.

### Example 14

Table 1 shows results of the tests for confirming the formation of quantum dots on various materials induced by the laser irradiation.

This table shows results of experimentally confirming whether a plurality of structures each having a quantum dot shape can be simultaneously formed by irradiating the laser onto the surface of a solid material selected from the group consisting of a semiconductor, metal, alloy and ceramics, and whether these quantum dots are periodically arrayed. The nanosecond pulse laser was irradiated under the conditions of 4.0×10² to 4.0×10³ J/m²/pulse, 2 to 20 Hz, and the pulse number of 500 to 5000 pulses.

It is found from this table that a plurality of structures each having a quantum dot shape are simultaneously formed with one batch irradiation, and a structure arraying these quantum dots periodically can be created, similarly as in a semiconductor even in a solid material selected from a metal, alloy and ceramics.

TABLE 1

| | Materials to be Irradiated with Laser | | | |
|---|---|---|---|---|
| | | Alloy | Ceramics | Semiconductor |
| | Metal | Brass, | MgO, Al₂O₃, | Si, Ge, InAs, |
| | Al, | Gun- | TiO₂, ZrSiO₄, | GaAs, GaN, |
| | Cu, Ti | metal | YSZ | SiC, C |
| Possible/Impossible | ∘ | ∘ | ∘ | ∘ |
| to Form a Plurality | | | | |
| of Quantum Dots | | | | |
| Possible/Impossible | ∘ | ∘ | ∘ | ∘ |
| to Form Two- | | | | |
| Dimensional Array | | | | |
| Pattern of | | | | |
| Quantum Dots | | | | |

∘: Possible to Simultaneously Form a Plurality of Quantum Dots or to Form Two-Dimensional Array Pattern
x: Impossible to Simultaneously Form a Plurality of Quantum Dots or to Form Two-Dimensional Array Pattern

Finally, comparative example obtained in the research in accordance with the present invention will be briefly described by using actual data.

### Comparative Example 1

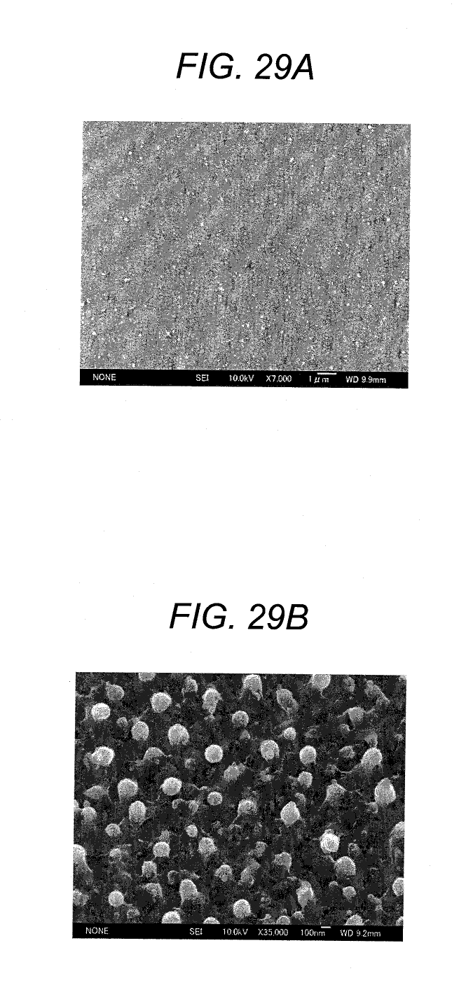

FIG. 29A is an SEM image illustrating a structure formed on the (100) surface of single crystal Si after the nanosecond pulse laser has been irradiated onto the surface (inclined angle θ=)0° by using Laser Inlite II-266) in the atmosphere and under the conditions of 0.33×10² J/m²/pulse and 10000 pulses.

FIG. 29B is an SEM image illustrating a structure formed on the (100) surface of single crystal Si after the nanosecond pulse laser has been irradiated onto the surface (inclined angle θ=0°) by using half-wavelength (266 nm) laser (Laser Inlite II-266) in the atmosphere and under the conditions of 0.50×10² J/m²/pulse and 2000 pulses.

It is found that a plurality of quantum dots are formed in each of the above two laser irradiation conditions; however, they are not periodically arrayed.

### Comparative Example 2

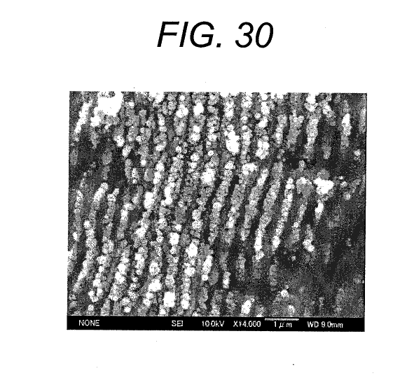

FIG. 30 is an SEM image illustrating a result of observing the surface of the Si-doped GaAs after the laser has been irradiated onto the surface by using Laser Inlite II-532 in the atmosphere and under the conditions of wavelength of 532 nm, inclined angle θ=0°, horizontal polarization, 100 mJ/pulse (3.5×10³ J/m²/pulse), 2 Hz, and the pulse number of 1000 pulses.

It is found that formation of a plurality of quantum dots and formation of ripple pattern-shaped undulations are observed; however, quantum dot-shaped objects in the ripple pattern-shaped undulation do not form the periodic array structures.

### Comparative Example 3

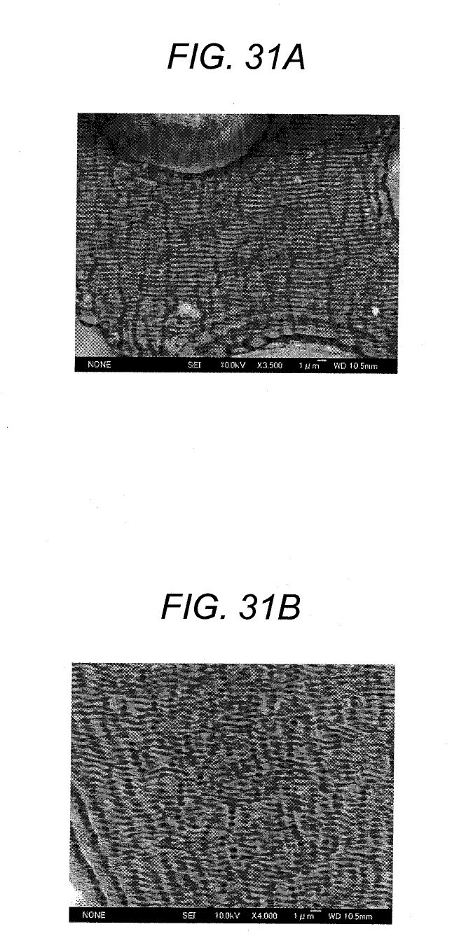

FIG. 31A is an SEM image illustrating the (100) surface of the single crystal Si after the femtosecond pulse laser has been irradiated onto the surface in the atmosphere and under the conditions of 1.3×10³ J/m²/pulse and 10000 pulses. FIG. 31B is an SEM image illustrating the surface of the 6H—SiC after the femtosecond pulse laser has been irradiated onto the surface under the conditions of 1.3×10³ J/m²/pulse and 1000 pulses.

It is found from these views that protrusion-depression patterns are formed on a surface when the femtosecond pulse laser is used; however, a plurality of quantum dots and a structure in which the quantum dots are periodically arrayed are not formed.

### Comparative Example 4

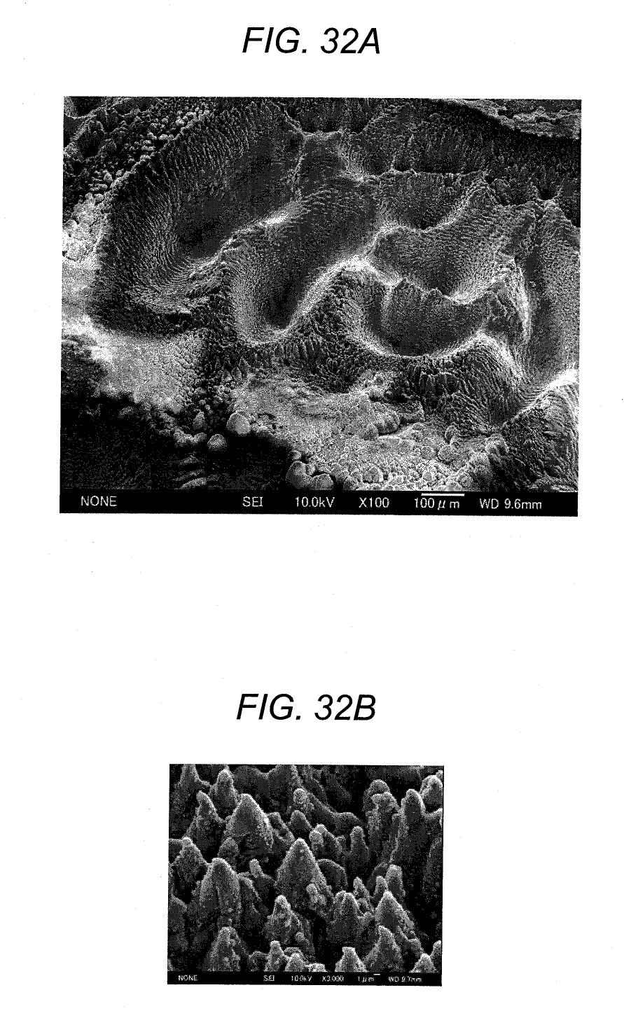

FIG. 32A is an SEM image illustrating the whole irradiated area on the (100) surface of single crystal Si irradiated with nanosecond pulse laser by using Laser Inlite II-532 in the atmosphere and under the conditions of a wavelength of 532 nm, inclined angle θ=0°, horizontal polarization, 10 kJ/m²/pulse, 20 Hz, and the pulse number of 2000 pulses.

FIG. 32B illustrates a cone-shaped (frog-shaped) organization formed in the periphery of the irradiated area illustrated in FIG. 32A, the organization having been enlarged.

This comparative example shows a result of SEM observation of a surface organization when the laser intensity is increased.

It is found from these views that a wave-shaped organization is formed at the center of the irradiated area and a cone-shaped (frog-shaped) organization is formed in the periphery of the irradiated area by increasing a laser irradiation intensity; however, a plurality of quantum dots and a structure in which the quantum dots have been periodically arrayed are not formed.

### Example 15

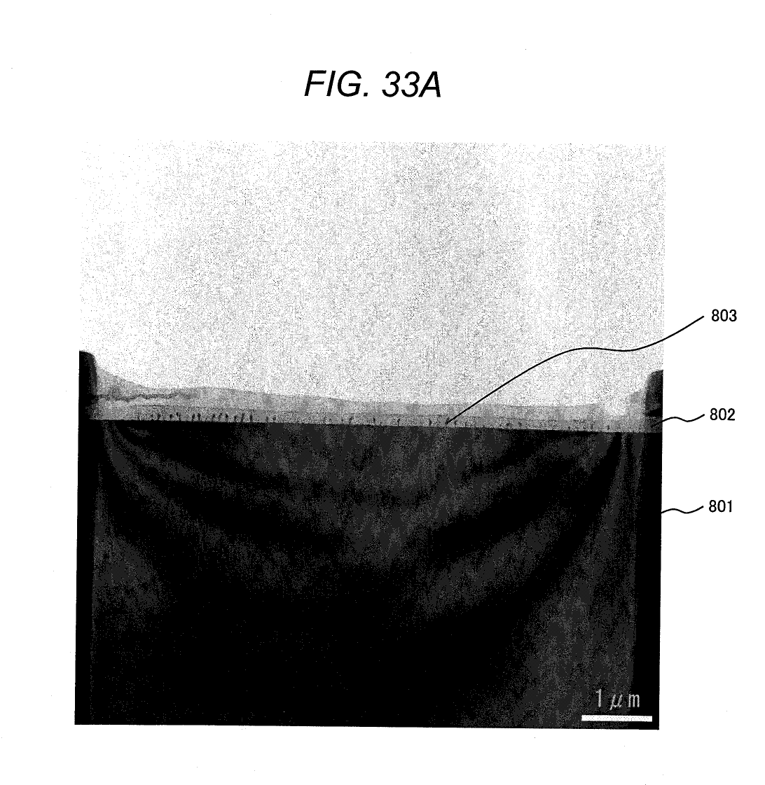

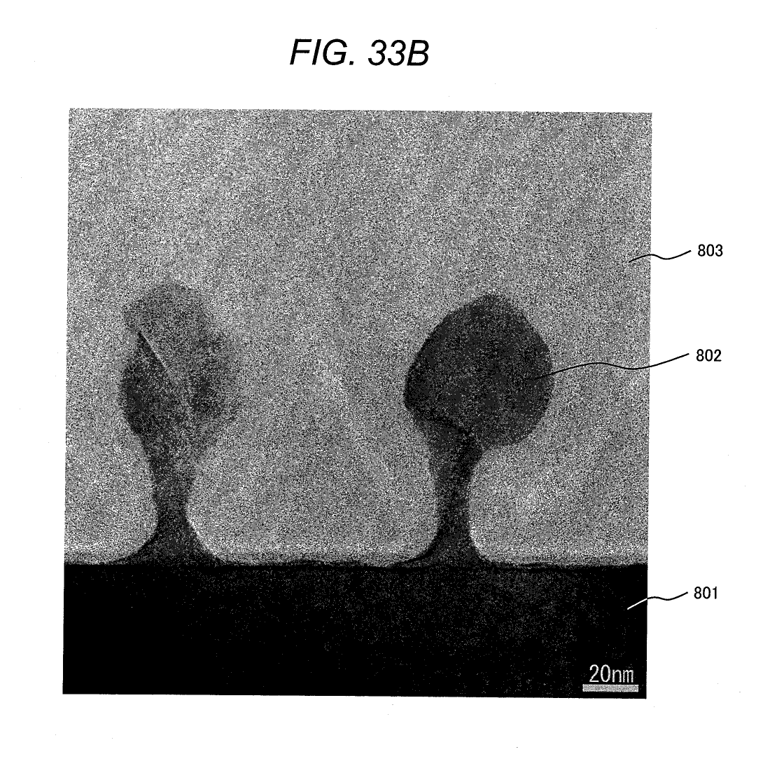

FIG. 33A is a sectional TEM image illustrating a quantum dot pattern according to another example.

FIG. 33E is a sectional TEM image illustrating the quantum dot pattern in FIG. 33A, the pattern having been enlarged.

In these views, a substrate 801 on which quantum dot patterns have been formed is made of Si, and a section of a quantum dot 803 has a shape obtaining by upending a flask or vidro on the surface of the substrate 801 irradiated with the laser. That is, the tip portion thereof is larger than the root portion thereof and the tip portion has a round bulge in the sectional shape of the quantum dot 803. This sectional shape is peculiar to the present invention, which can never be obtained by a top-down (chipping-off) method alone using the laser irradiation.

A quantum dot pattern in the present example has been fabricated under the conditions of 1500 pulses and 1.24 kJ/m² in the atmosphere.

Additionally, in the present example, a carbon protective layer 802 is formed on the surface of the substrate 801 by performing carbon (C) vapor deposition two times, on the surface of the substrate 801 where quantum dots 803 having been formed with the laser irradiation. Subsequently, the surface shape was protected and fixed by performing tungsten (W) deposition, so that a sample (thickness: 100 nm) for observing the section of the quantum dot 803 was fabricated by a Focused Ion Beam (FTB) processing. The sample was used in the TEM observation.

According to the present invention, both functions of the patterning using the coherency of the laser beam (top-down method) and the self-organization of the surface atoms under the irradiation of the laser beam (bottom-up method) can be simultaneously exhibited, thereby allowing the patterning of the surface quantum dots to be made.

Accordingly, a method for fabricating a quantum dot formed-surface by the laser irradiation can be provided in which structures each having a quantum dot shape which cannot be conventionally achieved with one batch laser irradiation can be induced with one batch laser irradiation and be periodically arrayed.

Further, a method for fabricating a quantum dot formed-surface can be provided in which periodic arrays each having structures with a quantum dot shape form a linear or curved two-dimensional pattern.

Furthermore, an electronic and electromagnetic device, quantum dot device, optoelectronic device, quantum dot solar cell, patterned catalyst material, functional material for functional device and patterned media, quantum dot laser, optical amplifier and a device structure for quantum cryptography communication and quantum computer, etc. having more excellent performance can be provided by using a fabrication method according to the present invention.

### REFERENCE NUMERALS

1: Ripple Pattern Sequence, 2: Surface Quantum Dot, 3: QuantumDot, 4: Crystal Orientation, 5: Substrate, 6: Crystal Orientation, 7: Quantum Dot Surface Area, 8: Electron Diffraction Pattern, 101: Laser Transmitter, 102: Irradiated Area, 103: Optical System Platen, 261: Quantum Dot Ripple Area, 262: Area other than Quantum Dot Ripple Area.

1. A method for fabricating a quantum dot-formed surface comprising a step of:
irradiating at least one batch of laser onto a surface of a solid material to simultaneously form a plurality of quantum dots arranged into periodic arrays on the surface.

2. The method according to claim 1,
wherein the step is one in which the arrays are arranged into a two-dimensional pattern by sequentially performing the laser irradiations at multiple times,
wherein each of the laser irradiations performs a superimposed irradiation onto the same area of the surface by using a plurality of polarized light each having an incident angle with respect to the surface, the incident angle being different from the others.

3. The method according to claim 1,
wherein the arrays are arranged into a two-dimensional pattern by using the laser irradiation performing a superimposed irradiation on the same area of the surface at the same time by using a plurality of polarized light each having an incident angle with respect to the surface, the angle being different from the others.

4. The method according to claim 1,
wherein the sequences constitute a two-dimensional pattern aligned with each other in a linear or curved line.

5. The method according to claim 1,
wherein the laser irradiation performs a surface dots-arraying at the same time with using a polarized pulse laser irradiation under reduced pressure or the atmosphere without using a collecting lens, the surface dots-arraying being both of forming periodic structures by the wave nature of the laser used in the laser irradiation; and forming short-periodic structures by a bottom-up method using a self-organization function of atoms of the surface, the short-periodic structures having an interval shorter than a wavelength of the laser.

6. The method according to claim 5,
wherein the laser is a nanosecond pulse laser, and conditions of irradiating the laser is 4.0×10² to 4.0×10³ J/m²/pulse, 2 to 20 Hz, and a pulse number thereof is 500 to 5000 pulses.

7. The method according to claim 5,
wherein diameters of the quantum dots are 1 to 100 nm, and heights of the quantum dots can be freely controlled up to 1 μm by changing an irradiation amount.

8. The method according to claim 5,
wherein a crystal having striped undulations which is formed by aligning the quantum dots with each other undergoes an epitaxial growth from the surface.

9. The method according to claim 1,
wherein the laser irradiation performs forming a two-dimensional pattern of the quantum dots by using a sequential irradiation or a superimposed irradiation.

10. The method according to claim 1,
wherein the laser irradiation is performed with an in situ observation of the quantum dots to be formed on the surface of the solid material fixed in an electron microscope containing a laser generator.

11. The method according to claim 1,
wherein the laser irradiation is performed in the atmosphere by using a laser oscillator-integrated optical and sample-fixing platen.

12. A quantum dot-formed surface structure having a periodic array of a plurality of quantum dots formed on a surface of a solid material by irradiating at least one batch of laser onto the surface,
wherein the array includes a linear or curved sequence of the quantum dots having a peak-to-peak distance of the plurality of quantum dots shorter than the wavelength of the laser used in the laser irradiation.

13. The quantum dot-formed surface structure according to claim 12,
wherein the array includes a plurality of linear sequences of the quantum dots in each of which the peak-to-peak distance of the plurality of quantum dots is shorter than the wavelength of the laser, and a distance between peaks of the quantum dots forming each of the sequences in adjacent sequences is longer than the peak-to-peak distance within a single sequence.

14. The quantum dot-formed surface structure according to claim 13,
wherein the distance is within an error range of 10% or less with respect to the wavelength, and the peak-to-peak distance is ¼ to ⅕ times the wavelength.

15. The quantum dot-formed surface structure according to claim 12,
wherein the curved sequence forms a circular line.

16. The quantum dot-formed surface structure according to claim 12,
wherein a crystal having striped undulations which is formed by aligning the quantum dots with each other is formed by an epitaxial growth from the surface that is a foundation.

17. An electronic and electromagnetism device comprising the quantum dot-formed surface structure according to claim 12.

18. A quantum dot device comprising the quantum dot-formed surface structure according to claim 12.

19. An optoelectronic device comprising the quantum dot-formed surface structure according to claim 12.

20. A solar cell comprising the quantum dot-formed surface structure according to claim 12.

21. A patterned catalyst material comprising the quantum dot-formed surface structure according to claim 12.

22. A functional device comprising the quantum dot-formed surface structure according to claim 12.

23. A functional material for a patterned media comprising the quantum dot-formed surface structure according to claim 12.

24. A quantum dot laser comprising the quantum dot-formed surface structure according to claim 12.

25. An optical amplifier comprising the quantum dot-formed surface structure according to claim 12.

26. A device for a quantum cryptography communication and quantum computers comprising the quantum dot-formed surface structure according to claim 12.

27. The optoelectronic device according to claim 19 having a photoluminescence peak near 600 nm.

28. The quantum dot device according to claim 18 having a photoluminescence peak near 600 nm.

29. The patterned catalyst material according to claim 21,
wherein the surface has a striped undulation area, and a value of a work function in the striped undulation area is 5.6 eV or more.

30. The functional surface device according to claim 22,
wherein the surface has a striped undulation area, and a value of a work function in the striped undulation area is 5.6 eV or more.

31. A quantum dot formed-surface structure constituted so as to pattern a plurality of quantum dot structures on the surface by simultaneously forming a plurality of quantum dots with a laser irradiation.

32. A quantum dot device constituted so as to pattern a plurality of quantum dot structures on the surface by simultaneously forming a plurality of quantum dots with a laser irradiation.

33. A quantum dot formed-surface structure constituted so as to pattern a plurality of quantum dot structures on the surface by simultaneously forming a plurality of quantum dots with a laser irradiation, crystals of the plurality of quantum dots having a uniform material formed by an epitaxial growth from the crystals of foundation thereof.

34. A quantum device constituted so as to pattern a plurality of quantum dot structures on the surface by simultaneously forming a plurality of quantum dots with a laser irradiation, crystals of the plurality of quantum dots having a uniform material formed by an epitaxial growth from the crystals of foundation thereof.
